(19) United States
(12) Patent Application Publication
(10) Pub. No.: US 2008/0099922 A1
(43) Pub. Date: May 1, 2008

(54) CIRCUIT DEVICE AND MANUFACTURING METHOD THEREOF

(76) Inventor: Noriaki Sakamoto, Gunma (JP)

Correspondence Address: FISH & RICHARDSON P.C., P.O. BOX 1022, MINNEAPOLIS, MN, 55440-1022, US

(21) Appl. No.: 11/554,472

(22) Filed: Oct. 30, 2006

(51) Int. Cl. H01L 23/52; H01L 23/48; H01L 29/40; H01L 21/00

(52) U.S. Cl. 257/758; 438/106

(57) ABSTRACT

A first insulating layer is formed on a front surface of a rectangular circuit board. Conductive patterns having a predetermined shape are formed on a front surface of the first insulating layer. A semiconductor element and a chip element are electrically connected to the conductive patterns by use of solder or conductive paste. The conductive patterns, the semiconductor element and the chip element which are formed on the front surface of the circuit board, are covered with a sealing resin. Pads on the circuit board and leads are connected to each other by use of thin metal wires.

### BACKGROUND OF THE INVENTION

1. Field of the Invention

The present invention relates to a circuit device and a manufacturing method thereof, and more particularly relates to a circuit device in which an electric circuit including conductive patterns and circuit elements is formed on a surface of a circuit board, and to a manufacturing method thereof.

2. Description of the Related Art

With reference to FIG. 19, a configuration of a conventional hybrid integrated circuit device 100 will be described. This technology is described for instance in Japanese Patent Application Publication No. Hei 5 (1993)-102645. Conductive patterns 103 are formed on a surface of a rectangular substrate 101 with an insulating layer 102 interposed therebetween. On a surface of the insulating layer 102, each of circuit elements 105 is fixed to a desired spot in the conductive patterns 103 to form a predetermined electric circuit. Here, as the circuit elements, a semiconductor element and a chip element are connected to the conductive patterns 103. Each of leads 104 is connected to a corresponding one of pads 109 which are formed in peripheral portions of the substrate 101, and which are respectively made of the conductive patterns 103, and functions as an external terminal. A sealing resin 108 has a function of sealing the electric circuit formed on the surface of the substrate 101.

There are two structures of the sealing resin 108. As a first structure, the sealing resin 108 is formed in a way that a back surface of the substrate 101 is exposed. By use of this structure, heat can be well released through the substrate 101 exposed to the outside. As a second structure, the sealing resin 108 is formed in a way that the entire device including the back surface of the substrate 101 is covered with the sealing resin 108. By use of this structure, breakdown voltage characteristic and moisture resistance of the substrate 101 can be secured. In FIG. 19, the entire device including the back surface of the substrate 101 is sealed. A thickness T5 of a portion of the sealing resin 108 covering the back surface of the substrate 101 is, for example, about 0.5 mm. Particularly, in a case where the substrate 101 is connected to a ground potential, the second structure described above is adopted, and the substrate 101 is insulated from the outside.

With reference to FIG. 20, another configuration of the conventional hybrid integrated circuit device 100 will be described. Here, a substrate connection part 110 is provided to a substrate 101. The substrate connection part 110 is a part in which the substrate 101 made of metal is electrically connected to one of conductive patterns 103. In the substrate connection part 110, an insulating layer 102 is partially removed to expose a surface of the substrate 101. Moreover, the substrate 101 in the exposed portion and one of the conductive patterns 103 are connected to each other with a thin metal wire 107. As described above, by electrically connecting the substrate 101 to one of the conductive patterns 103, the conductive patterns 103 and the substrate 101 can be set at the same potential. Thus, a parasitic capacity generated between the conductive patterns 103 and the substrate 101 can be reduced.

However, in a case where the sealing resin 108 is formed in a way that the back surface of the substrate 101 is covered with the sealing resin 108, there is a problem that heat release properties of the entire device are deteriorated since the sealing resin 108 covering the back surface of the substrate 101 has poor thermal conductivity.

Improvement in the heat release properties can be expected when the thickness (T5) of the sealing resin 108 covering the back surface of the substrate 101 is reduced. However, when the thickness T5 of the sealing resin 108 is set at 0.5 mm or less, there is a problem that the resin is not entirely applied to the back surface of the substrate 101 in a molding step of forming the sealing resin 108 by injection molding.

When the back surface of the substrate 101 is exposed to the outside in order to improve the heat release properties, there is a problem that insulation properties insulating the substrate 101 from a radiation fin, with which the substrate 101 is in contact, cannot be secured. Moreover, there is also a problem that connection strength between the substrate 101 and the sealing resin 108 is lowered. Furthernore, there is a problem that moisture enters the device through an interface between a side face of the substrate 101 and the sealing resin 108.

The substrate 101 is supported with the leads 104 in the middle of a manufacturing process. Accordingly, in order to increase bonding strength between the leads 104 and the substrate 101, a planar size of each of the pads 109 is set as large as, for example, about 1 mm×1 mm or more. As a result, there is a problem that the number of pads 109, which can be formed on one substrate, is reduced.

In the hybrid integrated circuit device 100 described above, back surfaces of the leads 104 are respectively fixed to the pads 109 by use of a conductive adhesive such as solder. However, insufficient fixing strength of the adhesive causes a problem that the leads 104 are detached from the respective pads 109 because of external force such as thermal stress.

In the hybrid integrated circuit device 100 described above, in order to electrically connect the substrate 101 to one of the conductive patterns 103, it is necessary to provide the substrate connection part 110 which penetrates the insulating layer 102. Furthermore, it is necessary to extend one of the conductive patterns 103 from a corresponding one of the pads 109 to the substrate connection part 110. Thus, there are problems that the configuration of the entire device is complicated, and that manufacturing costs are also increased.

### SUMMARY OF THE INVENTION

The present invention has been made in consideration of the foregoing problems. The main object of the present invention is to provide a circuit device in which moisture resistance is improved, and in which a number of pads can be formed on a circuit board, and to provide a manufacturing method thereof. The present invention has been made in further consideration of the foregoing problems. The main object of the present invention is to provide a circuit device in which fixing strength between a circuit board and leads is improved, and to provide a manufacturing method thereof.

A circuit device of the present invention includes a circuit board on a front surface of which conductive patterns, pads respectively made of the conductive patterns and circuit elements connected to the conductive patterns are formed a metal board attached to a back surface of the circuit board a sealing resin which covers at least peripheral portions respectively of the front surface, side faces and the back surface of the circuit board in a state where the back surface of the metal board is exposed to the outside, and leads which are respectively connected to the pads through thin metal wires, and which have ends drawn out from the sealing resin.

A method of manufacturing a circuit device of the present invention includes the steps of preparing a lead frame which includes a land connected to an outer frame with hanging leads and a plurality of leads each having one of ends thereof disposed in a way that the land is surrounded by the ends of the lands mounting, on the land, a circuit board on a front surface of which conductive patterns, pads respectively made of the conductive patterns and circuit elements connected to the conductive patterns are formed electrically connecting the pads on the circuit board to the respective leads by use of thin metal wires, and forming a sealing resin in a way that the sealing resin covers portions of the respective leads connected to the thin metal wires, the circuit board and the thin metal wires.

A method of manufacturing a circuit device of the present invention includes the steps of preparing a lead frame which includes a land connected to an outer frame with hanging leads and a plurality of leads each having one of ends thereof disposed in a way that the land is surrounded by the ends of the lands; mounting, on the land, a circuit board on a front surface of which conductive patterns, pads respectively made of the conductive patterns and circuit elements connected to the conductive patterns are formed electrically connecting the pads on the circuit board to the respective leads by use of thin metal wires, and mechanically bonding at least two of the leads to the circuit board partially removing the hanging leads in regions respectively corresponding to peripheral portions of the circuit board, and forming a sealing resin in a way that the sealing resin covers portions of the respective leads connected to the thin metal wires, the circuit board and the thin metal wires.

A circuit device of the present invention includes a circuit board which is made of a conductive material, and which has a surface thereof covered with an insulating layer conductive patterns formed on a surface of the insulating layer circuit elements electrically connected to the conductive patterns, and leads respectively connected to pads each made of the conductive pattern. In the circuit device, at least one of the leads is connected to a corresponding one of protrusions obtained by causing the circuit board to partially protrude in its thickness direction.

A method of manufacturing a circuit device of the present invention includes the steps of forming an electric circuit including conductive patterns and circuit elements on a surface of a circuit board made of a conductive material fixing each of leads to a corresponding one of pads respectively made of the conductive patterns and electrically connecting at least one of the leads to the circuit board. In the method, protrusions, which are obtained by causing the circuit board to partially protrude in its thickness direction, are provided and the leads are connected to the circuit board by caulking the leads to the respective protrusions.

A method of manufacturing a circuit device of the present invention includes the steps of preparing a lead frame including a plurality of leads disposed in a way that a region on which a circuit board is mounted, is surrounded by the leads, preparing the circuit board on a front surface of which conductive patterns, pads respectively made of the conductive patterns and circuit elements connected to the conductive patterns are formed, and in which protrusions protruding in the thickness direction of the circuit board are provided, fixing the circuit board to the lead frame by caulking at least two of the leads respectively to corresponding ones of the protrusions in the circuit board, and electrically connecting the pads on the circuit board to the respective leads, and sealing at least a surface of the circuit board with a sealing resin in a state where the circuit board is fixed to the lead frame by use of the protrusions.

A method of manufacturing a circuit device of the present invention includes the steps of preparing a lead frame which includes a land connected to an outer frame with hanging leads and a plurality of leads each having one of ends thereof disposed in a way that the land is surrounded by the ends of the leads mounting, on the land, a circuit board on a front surface of which conductive patterns, pads respectively made of the conductive patterns and circuit elements connected to the conductive patterns are formed caulking at least two of the leads respectively to corresponding ones of protrusions provided by causing the circuit board to partially protrude in its thickness direction partially removing the hanging leads in regions respectively corresponding to peripheral portions of the circuit board, and sealing at least the front surface of the circuit board with a sealing resin in a state where the circuit board is fixed to the lead frame by use of the protrusions.

### BRIEF DESCRIPTION OF THE DRAWINGS

FIG. 1A is a perspective view and FIG. 1B is a cross-sectional view showing a circuit device of a preferred embodiment of the present invention.

FIG. 2 is a cross-sectional view showing the circuit device of the preferred embodiment of the present invention.

FIG. 3A is a plan view and FIG. 3B is a cross-sectional view showing the circuit device of the preferred embodiment of the present invention.

FIG. 4A is a plan view, FIGS. 4B and 4C are cross-sectional views and FIG. 4D is a plan view showing a method of manufacturing a circuit device according to the preferred embodiment of the present invention.

FIG. 5A is a plan view and FIGS. 5B and 5C are cross-sectional views showing the method of manufacturing a circuit device according to the preferred embodiment of the present invention.

FIG. 6A is a cross-sectional view and FIG. 6B is a plan view showing the method of manufacturing a circuit device according to the preferred embodiment of the present invention.

FIG. 7A is a plan view and FIGS. 7B and 7C are cross-sectional views showing a method of manufacturing a circuit device according to the preferred embodiment of the present invention.

FIGS. 8A and 8B are cross-sectional views and FIG. 8C is a plan view showing the method of manufacturing a circuit device according to the preferred embodiment of the present invention.

FIG. 9A is a cross-sectional view and FIG. 9B is a plan view showing the method of manufacturing a circuit device according to the preferred embodiment of the present invention.

FIG. 10A is a perspective view FIG. 10B is a cross-sectional view and FIG. 10C is a perspective view showing a circuit device of the preferred embodiment of the present invention.

FIG. 11A is a plan view and FIG. 11B is a cross-sectional view showing the circuit device of the preferred embodiment of the present invention.

FIG. 12 is a cross-sectional view showing the circuit device of the preferred embodiment of the present invention.

FIG. 13A is a plan view FIG. 13B is a perspective view and FIG. 13C is a plan view showing a method of manufacturing a circuit device according to the preferred embodiment of the present invention.

FIG. 14A is a plan view and FIGS. 14B and 14C are cross-sectional views showing the method of manufacturing a circuit device according to the preferred embodiment of the present invention.

FIG. 15A is a cross-sectional view and FIG. 15B is a plan view showing the method of manufacturing a circuit device according to the preferred embodiment of the present invention.

FIG. 16A is a plan view and FIGS. 16B and 16C are cross-sectional views showing a method of manufacturing a circuit device according to the preferred embodiment of the present invention.

FIGS. 17A and 17B are cross-sectional views and FIG. 17C is a plan view showing the method of manufacturing a circuit device according to the preferred embodiment of the present invention.

FIG. 18A is a cross-sectional view and FIG. 18B is a plan view showing the method of manufacturing a circuit device according to the preferred embodiment of the present invention.

FIG. 19 is a cross-sectional view showing a conventional hybrid integrated circuit device.

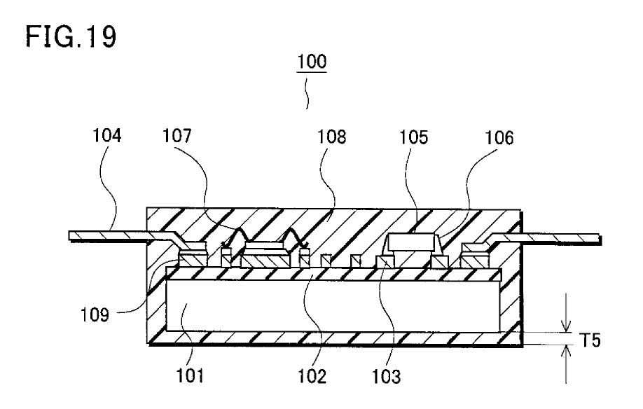

FIG. 20 is a cross-sectional view showing a conventional hybrid integrated circuit device.

### DESCRIPTION OF THE EMBODIMENTS

### First Embodiment

In this embodiment, descriptions will be provided for a structure of a hybrid integrated circuit device 10 as an example of a circuit device.

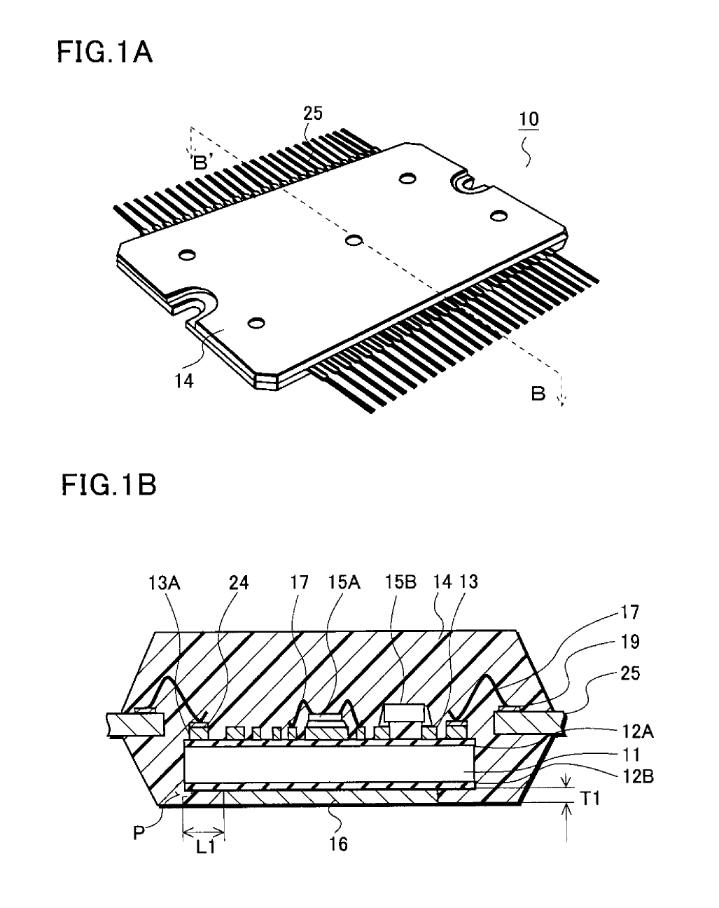

With reference to FIGS. 1A and 1B, descriptions will be provided for a configuration of the hybrid integrated circuit device 10 of the preferred embodiment of the present invention. FIG. 1A is a perspective view of the hybrid integrated circuit device 10 viewed from obliquely above. FIG. 1B is a cross-sectional view taken along the line B-B′ in FIG. 1A.

On a surface of a rectangular circuit board 11, a first insulating layer 12A is formed. Conductive patterns 13 having a predetermined shape are formed on a surface of the first insulating layer 12A. A semiconductor element 15A and a chip element 15B are electrically connected to predetermined spots in the conductive patterns 13 by use of solder or conductive paste. The conductive patterns 13, the semiconductor element 15A and the chip element 15B, which are formed on the surface of the circuit board 11, are covered with a sealing resin 14.

The circuit board 11 is a metal board mainly made of metal such as aluminum (Al) and copper (Cu). A specific size of the circuit board 11 is, for example, about 30 mm in length, 15 mm in width and 0.5 mm in thickness. Copper is suitable as a material of the circuit board 11. The circuit board 11 mainly made of copper has small warpage due to a temperature change or the like, and has sufficient mechanical strength even when the thickness thereof is as small as about 0.5 mm. In a case where a board made of aluminum is adopted as the circuit board 11, both principal surfaces of the circuit board 11 are subjected to alumite treatment.

By adopting copper as the material of the circuit board 11, a gold-plated film or a silver-plated film can be easily formed on a surface of the conductive patterns 13 formed on the circuit board 11. This is because the circuit board 11 made of copper is not dissolved even when the circuit board 11 is soaked in an electrolyte for plating processing in order to form the gold-plated film or the silver-plated film on the surface of the conductive patterns 13. Meanwhile, when the board made of aluminum is soaked in an electrolyte for gold plating processing, aluminum may be dissolved in the electrolyte and may contaminate the electrolyte. For this reason, in a case where the circuit board 11 made of aluminum is subjected to gold plating processing, it is necessary to protect a surface on which aluminum is exposed by use of a resin film or the like.

The first insulating layer 12A is formed in a way that the first insulating layer 12A covers the entire upper surface of the circuit board 11. The first insulating layer 12A is made of an epoxy resin highly filled with fillers such as Al₂O₃, and the like. Thus, heat generated from the circuit elements included in the circuit device can be actively released to the outside through the circuit board 11. A specific thickness of the first insulating layer 12A is, for example, about 50 μm. The insulating layer 12A having this thickness can secure a breakdown voltage (insulation breakdown voltage) of 4 KV.

A second insulating layer 12B is formed in a way that the second insulating layer 12B covers a back surface of the circuit board 11. The second insulating layer 12B may have the same composition and thickness as those of the first insulating layer 12A. By covering the back surface of the circuit board 11 with the second insulating layer 12B, breakdown voltage characteristic of the back surface of the circuit board 11 can be secured. Here, the back surface of the circuit board 11 and an upper surface of a metal board 16 are insulated from each other by the second insulating layer 12B.

The conductive patterns 13 are made of metal such as copper, and are formed on the surface of the first insulating layer 12A so that a predetermined electric circuit is realized. Moreover, on sides from which leads 25 are drawn out, pads 13A respectively made of the conductive patterns 13 are formed. Here, FIG. 1B shows the single-layer conductive patterns 13. However, multilayer conductive patterns 13 each including layers superposed with insulating layers interposed between each layer may be formed on the upper surface of the circuit board 11.

A plurality of the pads 13A are disposed in peripheral portions of the circuit board 11, and thin metal wires 17 having a diameter of about 30 μm are respectively wire-bonded to upper surfaces of the pads 13A. The plurality of pads 13A are disposed in the peripheral portions along opposite sides of the circuit board 11. The pads 13A may have a size large enough for wire bonding of the thin metal wires 17, and a planar size thereof is, for example, about 200 μm×200 μm. In order to perform wire bonding of the thin metal wires 17 made of gold (Au), the upper surfaces of the pads 13A are covered with plated films 24 made of gold (Au). As described above, in the first embodiment, the planar size of each of the pads 13A can be set smaller than that of the conventional example. Thus, more the pads 13A can be formed on the circuit board 11.

The circuit elements including the semiconductor element 15A and the chip element 15B are fixed to the predetermined spots in the conductive patterns 13. A transistor, an LSI chip, a diode or the like is adopted as the semiconductor element 15A. In this event, the semiconductor element 15A and the conductive patterns 13 are connected to each other through the thin metal wires 17. A chip resistor, a chip capacitor or the like is adopted as the chip element 15B. An element, such as an inductance, a thermistor, an antenna and an oscillator, which has electrode parts respectively at both ends thereof is adopted as the chip element 15B,. Furthermore, as the circuit element, a resin-sealed package and the like can also be fixed to the conductive patterns 13.

One end of each of the leads 25 is electrically connected to a corresponding one of the pads 13A on the circuit board 11, and the other end thereof is drawn out to the outside from the sealing resin 14. The leads 25 are made of metal mainly made of copper (Cu), aluminum (Al), Fe—Ni alloy or the like. The pads 13A formed on the upper surface of the circuit board 11 are connected to the respective leads 25 with the thin metal wires 17 made of gold (Au) or the like having a diameter of about 30 μm. Plated films 19 made of gold (Au) are formed on surfaces of the leads 25 to which the thin metal wires 17 are respectively connected.

In this event, the leads 25 are connected to the respective pads 13A provided along two opposite sides of the circuit board 11. However, the pads 13A may be provided along one side or four sides of the circuit board 11, and the leads 25 may be connected to the respective pads 13A.

The sealing resin 14 is formed by transfer molding using a thermosetting resin or by injection molding using a thermoplastic resin. In FIG. 1B, the conductive patterns 13, the semiconductor element 15A, the chip element 15B and the thin metal wires 17 are sealed with the sealing resin 14. Moreover, the surface and side faces of the circuit board 11 are covered with the sealing resin 14. Peripheral portions of the back surface of the circuit board 11 alone are covered with the sealing resin 14. The vicinity of a center portion of the back surface of the circuit board 11 is not covered with the sealing resin 14, and the metal board 16 is attached thereto. Here, the sealing resin 14 may be formed in a way that the sealing resin 14 also covers the back surface of the circuit board 11.

With reference to FIG. 1B, the vicinity of the peripheral portion of the back surface of the circuit board 11 is covered with the sealing resin 14. In FIG. 1B, L1 denotes a width of a region covered with the sealing resin 14. Although this L1 varies depending on a required withstand voltage, L1 is preferably set at about 2 mm to 3 mm or more. Hence, a withstand voltage at edges P of the circuit board 11 can be secured. Specifically, in a case where L1 is 2 mm, the breakdown voltage of 2 KV at the edges P can be secured. In a case where L1 is 3 mm, the breakdown voltage of 3 KV at the edges P can be secured. Note that a portion of the sealing resin 14 covering the back surface of the circuit board 11 has a thickness T1 of, for example, about 0.3 mm.

In the first embodiment, by covering the peripheral portions of the back surface of the circuit board 11 with the sealing resin 14, breakdown voltage characteristic of the edges P of the circuit board 11 can be secured. Specifically, the first and second insulating layers 12A and 12B are formed respectively on the entire upper and back surfaces of the circuit board 11. Thereby, breakdown voltage characteristic of the upper and back surfaces of the circuit board 11 is secured by the first and second insulating layers 12A and 12B. On the other hand, the side faces of the circuit board 11 are not covered with resin layers, and metal surfaces are exposed on the side faces of the circuit board 11. For this reason, in order to secure insulation of the circuit board 11, it is necessary to prevent short-circuiting between the side faces (particularly, the edges P) of the circuit board 11 and the outside through an interface between the circuit board 11 and the sealing resin 14. To this end, in the first embodiment, the sealing resin 14 is formed in the peripheral portion of the back surface of the circuit board 11 in a manner that the edges P are separated from the outside. Specifically, the sealing resin 14 is formed in a way that the edges P are respectively surrounded by the sealing resin 14. Accordingly, breakdown voltage characteristic of the entire circuit board 11 is secured.

In the first embodiment, only the peripheral portion of the back surface of the circuit board 11 is covered with the sealing resin 14, and the other region in the back surface of the circuit board 11 is in contact with the metal board 16. Thus, heat generated by driving the semiconductor element 15A and the like is well released to the outside through the circuit board 11 and the metal board 16. By covering the peripheral portion of the back surface of the circuit board 11 with the sealing resin 14, an anchor effect is achieved to improve bonding strength between the circuit board 11 and the sealing resin 14. Furthermore, since the peripheral portion of the back surface of the circuit board 11 is covered with the sealing resin 14, moisture resistance is also improved.

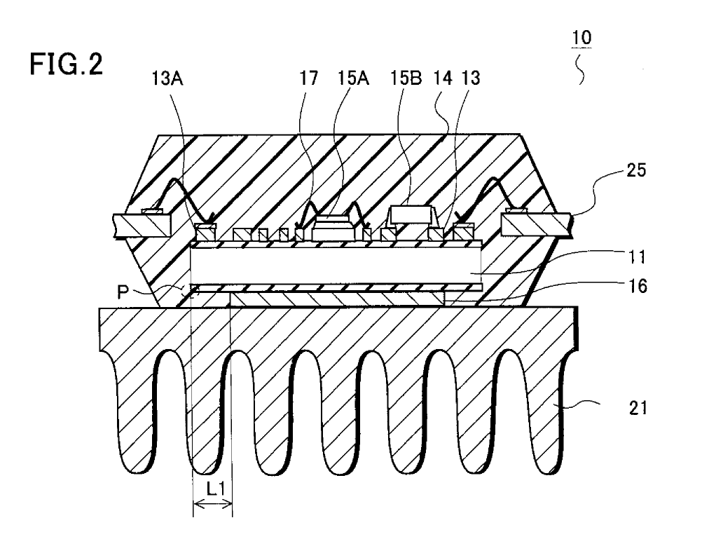

With reference to FIG. 2, a radiation fin 21 is fixed to a bottom of the hybrid integrated circuit device 10. The radiation fin 21 is made of metal such as copper and aluminum. In this respect, an upper surface of the radiation fin 21 is connected to the bottom of the hybrid integrated circuit device 10 through the metal board 16 exposed to a lower surface of the hybrid integrated circuit device 10. By use of this structure, the heat generated from the circuit elements including the semiconductor element 15A and the like is released to the outside through the circuit board 11, the metal board 16 and the radiation fin 21. As described above, since the peripheral portion of the back surface of the circuit board 11 is covered with the sealing resin 14, the withstand voltage at the edges P of the circuit board 11 is sufficiently secured. Hence, the radiation fin 21 and the circuit board 11 are insulated from each other.

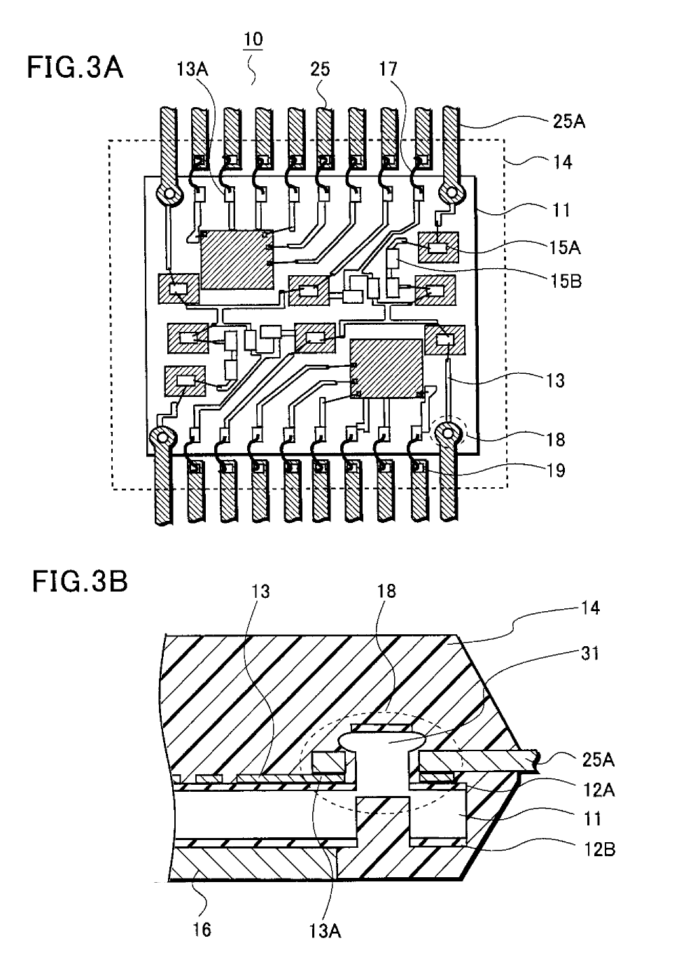

With reference to FIGS. 3A and 3B, the structure of the hybrid integrated circuit device 10 will be further described. FIG. 3A is a plan view of the hybrid integrated circuit device 10, and FIG. 3B is a cross-sectional view showing a fixing part 18 for mechanically connecting one of leads 25A to the circuit board 11.

With reference to FIG. 3A, the plurality of pads 13A provided to the peripheral portion of the circuit board 11 are respectively connected to the leads 25 through the thin metal wires 17. In this event, although all of the pads 13A on the circuit board 11 may be connected with the respective thin metal wires 17, some of the leads 25A may be mechanically connected to the circuit board 11. Here, the leads 25A respectively connected to the pads 13A each positioned at a corresponding one of four corners of the circuit board 11 are mechanically connected to the circuit board 11 by use of the respective fixing parts 18. As a structure of the fixing part 18, a back surface of the each of leads 25A may be fixed to a corresponding one of the pads 13A by use of a solder material (solder). Alternatively, a protrusion 31 is formed by causing the circuit board 11 to partially protrude, and one of the leads 25A may be caulked to this protrusion 31. Furthermore, the leads 25A and the circuit board 11 can be mechanically connected to each other by connecting the leads 25A positioned at the edges to the pads 13A by use of thick wires having a diameter of about 500 μm.

By providing the fixing parts 18, the circuit board 11 can be supported by the leads 25A in the middle of manufacturing steps. Since areas where the leads 25A and the respective pads 13A are in contact with each other are increased, current capacities at the spots where the leads 25A and the pads 13A are respectively connected to each other are increased as compared with the connection using the thin metal wires 17. Thus, the leads 25A can also be used as ground terminals or power supply terminals.

With reference to FIG. 3B, a specific structure of one of the fixing parts 18 will be described. In the fixing part 18, the protrusion 31 obtained by causing the circuit board 11 to partially protrude upward is used to caulk one of the leads 25A. To be more specific, the protrusion 31 is formed by subjecting the circuit board 11 to half blanking processing from the back surface of the circuit board 11 using a pressing machine so that the circuit board 11 is caused to partially protrude upward. A ring-shaped tip of one of the leads 25A is placed on the circuit board 11 in a manner that the tip surrounds the protrusion 31. The ring-shaped tip of the lead 25A is caulked by a pressure-deformed upper part of the protrusion 31. In the fixing part 18, the back surface of the lead 25A is in contact with the upper surface of the pad 13A, and the lead 25A and the pad 13A are electrically connected to each other. The lead 25A is also electrically connected to the circuit board 11 by the fixing part 18. Thus, the circuit board 11 can also be connected to a ground potential through the fixing part 18. Furthermore, in order to achieve more secure connection between the protrusion 31 and the lead 25A, solder or conductive paste may be applied to the fixing part 18.

### Second Embodiment

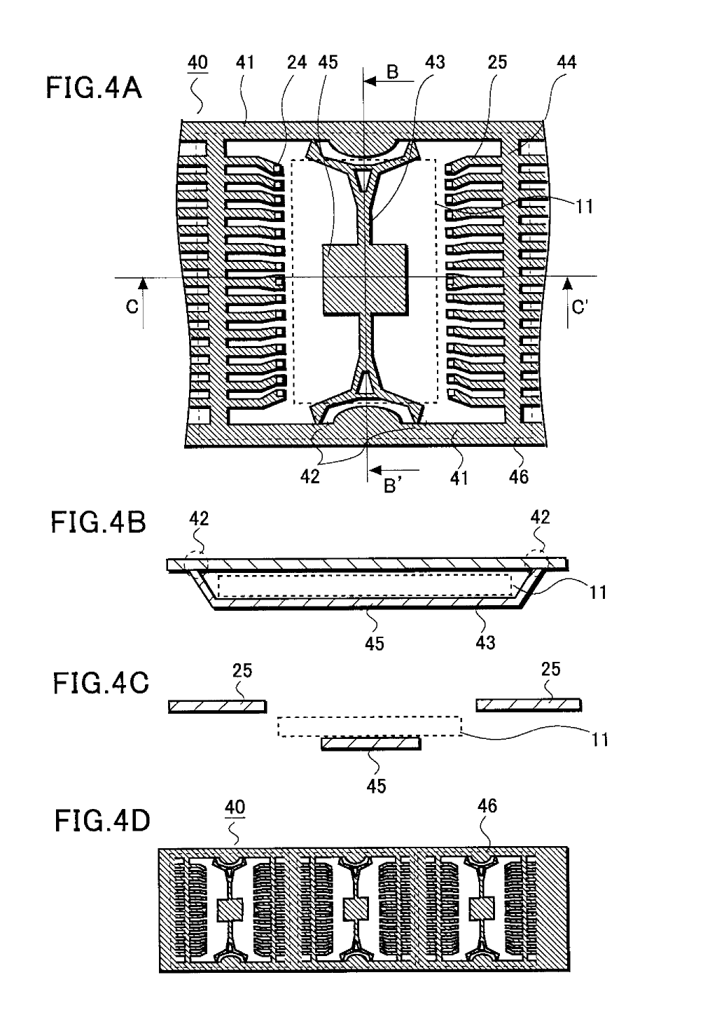

In this embodiment, with reference to FIGS. 4 to 6, descriptions will be provided for a method of manufacturing a hybrid integrated circuit device. In the manufacturing method of this embodiment, pads 13A on a circuit board 11 and leads 25 are respectively connected to each other by use of thin metal wires 17. Moreover, the hybrid integrated circuit device is manufactured by using a lead frame 40 in which a number of the leads 25 and land 45 are provided. In the middle of manufacturing steps, the lead frame 40 holds the circuit board 11 by fixing the circuit board 11 to the land 45.

With reference to FIGS. 4A to 4D, first, the lead frame 40, in which the lands 45 and the leads 25 are provided, is prepared. FIG. 4A is a plan view showing one of units 46 provided to the lead frame 40. FIG. 4B is a cross-sectional view taken along the line B-B′ in FIG. 4A. FIG. 4C is a cross-sectional view taken along the line C-C′ in FIG. 4A. FIG. 4D is a plan view showing the entire lead frame 40. In FIGS. 4A to 4D, the circuit board 11 to be mounted is indicated by a dotted line.

With reference to FIG. 4A, the unit 46 includes a number of the leads 25 each having one of ends thereof positioned close to a region on which the circuit board 11 is mounted; and the land 45 connected to an outer frame 41 of the lead frame 40 by use of hanging leads 43.

In the page space for FIG. 4A, the leads 25 are horizontally extended from both of right and left sides of the unit 46 toward the region on which the circuit board 11 is mounted. The plurality of the leads 25 are connected to one another by tie bars 44. Thereby, deformation of the leads is prevented. Plated films 24 are respectively formed on portions of upper surfaces of the leads 25 to which thin metal wires are connected in a subsequent step.

The land 45 is formed inside the region on which the circuit board 11 is mounted, and plays a role of mechanically supporting the circuit board 11 in the manufacturing steps. The land 45 is connected to the outer frame 41 of the lead frame 40 by the hanging leads 43 extended in a vertical direction in the page space for FIG. 4A. Connection parts 42, in which each of the hanging leads 43 and the outer frame 41 are connected to each other, are narrowed in width. Accordingly, the hanging leads 43 are easily separated from the outer frame 41 in a subsequent step. Here, by providing the two connection parts 42, the circuit board 11 is stably supported by the land 45 and the hanging leads 43. The land 45 also has a function of improving heat release properties of the entire device by remaining on the back surface of the circuit board 11.

With reference to the cross-sectional views of FIGS. 4B and 4C, the land 45 is positioned below the outer frame 41 with the hanging leads 43 bent downward. Thereby, the circuit elements and the like, which are mounted on the upper surface of the circuit board 11, can be positioned in the vicinity of the center of the device in its thickness direction. Accordingly, even in a case where an external factor, such as a temperature change, causes bending stress to act on the entire device, the stress acting on the circuit elements can be reduced. Hence, connection reliability of the circuit elements can be improved.

With reference to FIG. 4D, in the strip-shaped lead frame 40, the plurality of units 46 having the configuration as described above are disposed with a space between each of the units 46. In the second embodiment, the hybrid integrated circuit device is manufactured by providing the plurality of units 46 to the lead frame 40. Thus, wire bonding, a molding step and the like are collectively performed to improve productivity.

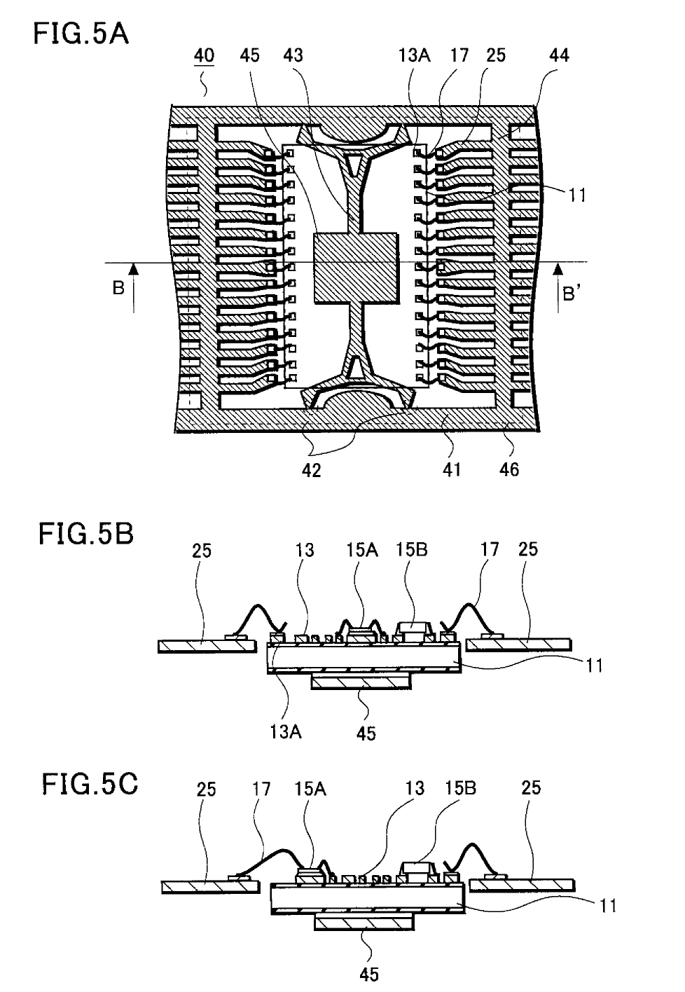

With reference to FIGS. 5A to 5C, subsequently, after the circuit board 11 is mounted on the land 45, the pads 13A formed on the surface of the circuit board 11 and the leads 25 are respectively connected to each other. FIG. 5A is a plan view of one of the units 46 on which the circuit board 11 is mounted, and FIGS. 5B and 5C are cross-sectional views each taken along the line B-B′ in FIG. 5A. Here, in FIG. 5A, the conductive patterns and the like, which are formed on the surface of the circuit board 11, are omitted.

With reference to FIGS. 5A and 5B, the circuit board 11, on which a conductive patterns 13, a semiconductor element 15A and the like are fixed, is fixed to the upper surface of the land 45 by use of a conductive or insulating adhesive. In this event, a number of the pads 13A are formed along two opposite sides of the circuit board 11. In order to improve bonding properties, surfaces of the respective pads 13A are gold-plated or silver-plated.

After the circuit board 11 is mounted, the pads 13A on the circuit board 11 are connected to the respective leads 25 by use of the thin metal wires 17. Since the upper surfaces of the pads 13A and the upper surfaces of the leads 25 are covered with plated films made of gold or the like, gold wires made of gold (Au) can be used as the thin metal wires 17. By adopting gold as a material of the thin metal wires 17, time required for wire bonding can be shortened. Thus, the productivity can be improved.

With reference to FIG. 5C, one of the leads 25 and the semiconductor element 15A are directly connected to each other by use of the thin metal wire 17. Thus, by directly connecting the semiconductor element 15A on the circuit board 11 to one of the leads 25, the configuration of the conductive patterns 13 on the circuit board 11 can be simplified.

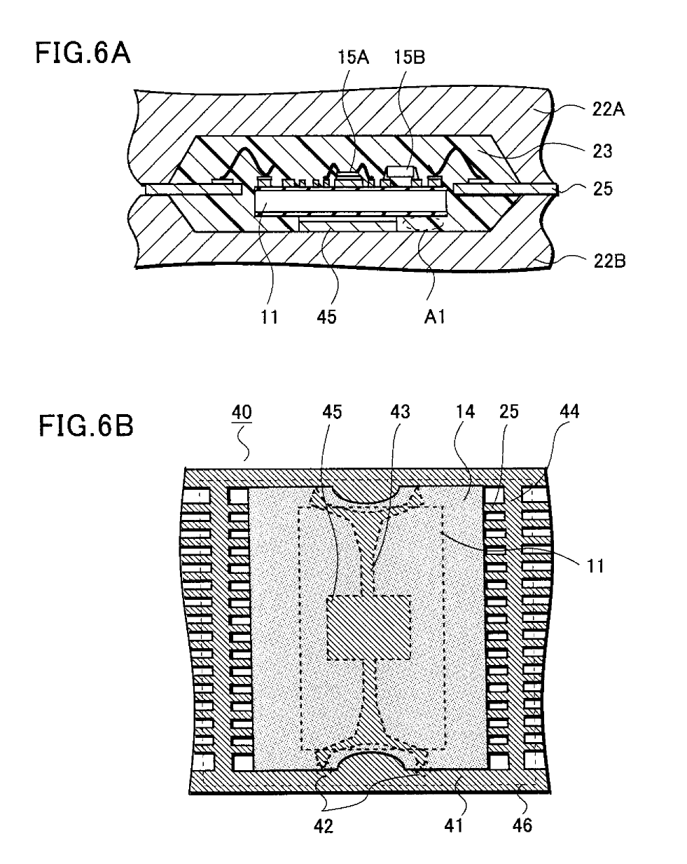

With reference to FIGS. 6A and 6B, a sealing resin is subsequently formed in a way that the sealing resin covers the circuit board 11. FIG. 6A is a cross-sectional view showing a step of molding the circuit board 11 by use of a mold. FIG. 6B is a plan view showing the lead frame 40 in a state after the molding is performed.

With reference to FIG. 6A, a back surface of the land 45 positioned below the circuit board 11 is first caused to be in contact with a lower mold 22B. Thereafter, by causing an upper mold 22A and the lower mold 22B to be in contact with each other, the circuit board 11 is housed inside a cavity 23. Subsequently, the circuit board 11 is sealed by injecting a resin into the cavity 23 through a gate (not shown) provided to the mold. In the second embodiment, since a region in the center of the back surface of the circuit board 11 is covered with the land 45, it is not necessary to apply the sealing resin to this region. Accordingly, it suffices that the sealing resin be applied only to a region A1 below the peripheral portion of the circuit board 11. Thus, it is made possible to prevent occurrence of voids not filled with the sealing resin. In this step, transfer molding using a thermosetting resin or injection molding using a thermoplastic resin is performed. Moreover, the unillustrated gate is provided to the vicinities of the hanging leads 43.

With reference to FIG. 6B, after the molding step described above is completed, the hanging leads 43 and the leads 25 are separated from the lead frame 40. Specifically, the hanging leads 43 are separated from the outer frame 41 at the spots where the connection parts 42 are provided. Since the connection parts 42 are formed to be narrow in width, the hanging leads 43 can be easily separated from the outer frame 41 by pressing a sealing resin 14. The leads 25 are separated at the spots where the tie bars 44 are provided, and the hybrid integrated circuit device as shown in FIGS. 1A and 1B is separated from the lead frame 40.

### Third Embodiment

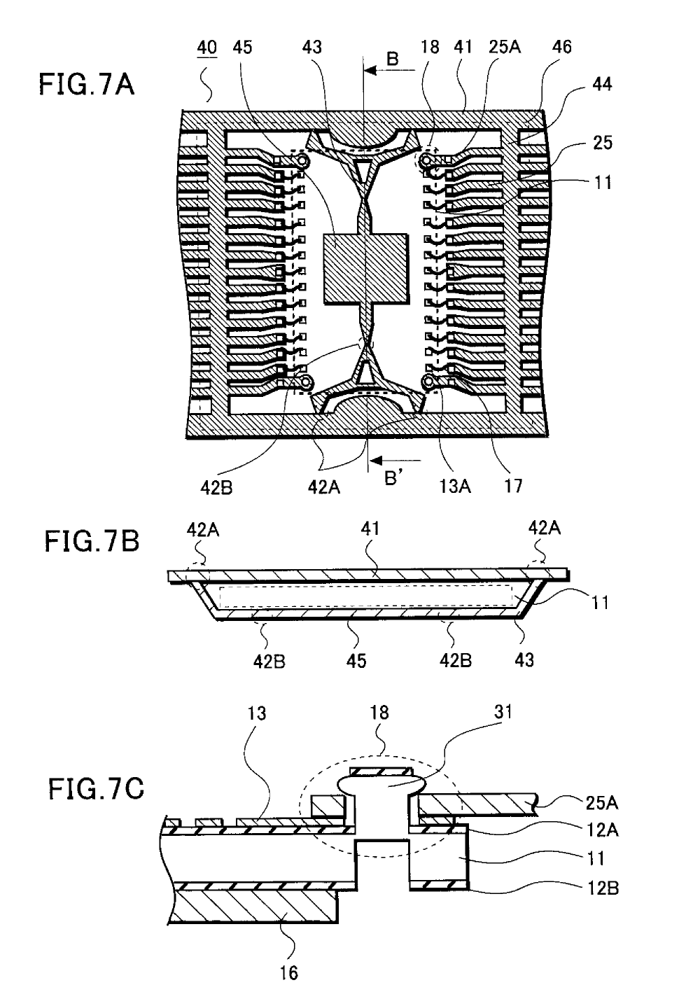

In this embodiment, with reference to FIGS. 7 to 9, descriptions will be provided for another method of manufacturing a hybrid integrated circuit device. A method of manufacturing a circuit device of this embodiment is basically the same as that of the second embodiment. In this embodiment, portions of respective hanging leads 43 each corresponding to one of the peripheral portions of a circuit board 11 are removed in the middle of the manufacturing steps. After the hanging leads 43 are removed, the circuit board 11 is mechanically supported by leads 25A. By removing the portions of the respective hanging leads 43 each positioned in one of the peripheral portions of the circuit board 11, short-circuiting between the hanging leads 43 and the circuit board 11 can be prevented in a hybrid integrated circuit device to be manufactured.

With reference to FIGS. 7A to 7C, the circuit board 11 is first fixed to a lead frame 40. FIG. 7A is a plan view of the lead frame 40. FIG. 7B is a cross-sectional view taken along the line B-B′ in FIG. 7A. FIG. 7C is a cross-sectional view showing a configuration of a fixing part 18 for fixing the circuit board 11.

With reference to FIGS. 7A and 7B, the circuit board 11 is fixed to the upper surface of a land 45 in the lead frame 40. Moreover, the pads 13A on the circuit board 11 are connected to the respective leads 25 through thin metal wires 17.

In the third embodiment, two connection parts 42A and 42B are provided to each of the hanging leads 43. Thereby, the hanging leads 43 positioned in the respective peripheral portions of the circuit board 11 can be separated from the lead frame 40. Specifically, the connection parts 42A are respectively provided to portions where parts of the hanging leads 43 and an outer frame 41 are respectively continuous with each other. The other connection parts 42B are provided respectively to intermediate portions of the hanging leads 43. The connection parts 42A and 42B are formed to be narrow in width. Thus, the hanging leads 43 can be partially removed.

Some of the leads 25A are mechanically connected to the circuit board 11 by use of the respective fixing parts 18. Here, four of the leads 25A are mechanically connected to the circuit board 11 respectively near four corners of the circuit board 11. By mechanically fixing the leads 25A to the circuit board 11, the circuit board 11 and the lead frame 40 can be maintained in a connected state even after the hanging leads 43 are removed. In this event, the leads 25A are respectively fixed to the corners of the circuit board 11. However, the leads 25A can be fixed to portions of the circuit board 11 other than the corners thereof. Furthermore, the number of the leads 25A need not be four The circuit board 11 can be fixed to the lead frame 40 by mechanically connecting at least two of the leads 25A to the circuit board 11.

With reference to FIG. 7C, in each of the fixing part 18, a protrusion 31 provided by causing the circuit board 11 to partially protrude is used to caulk a ring-shaped tip of one of the leads 25A. A specific configuration of the fixing part 18 is the same as that described in FIG. 3B.

In this event, the leads 25A and the circuit board 11 can also be mechanically connected to each other by use of a configuration other than caulking. Specifically, the leads 25A and the circuit board 11 can be mechanically connected to each other by connecting the pads 13A on the circuit board 11 to the respective leads 25A by use of thick wires having a diameter of about 500 μm. Alternatively, the leads 25A and the circuit board 11 can be mechanically connected to each other by using a bonding material such as solder to bond back surfaces of the leads 25A to the respective pads 13A.

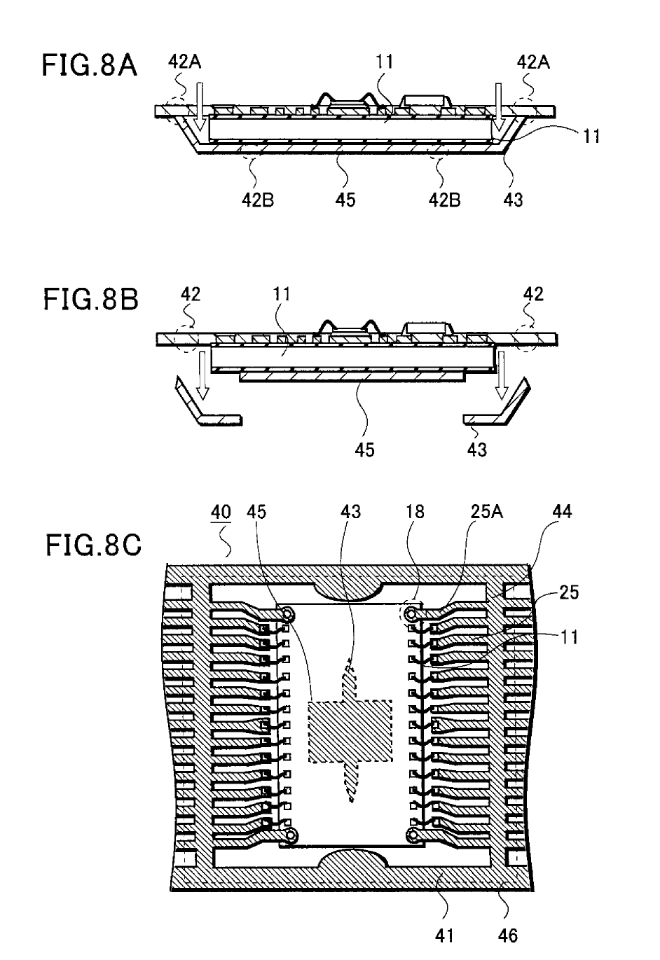

With reference to FIGS. 8A to 8C, subsequently, the hanging leads 43 respectively positioned in the peripheral portions of the circuit board 11 is separated from the lead frame 40. FIGS. 8A and 8B are cross-sectional views showing a state where the hanging leads 43 are partially separated. FIG. 8C is a plan view of the lead frame 40 in a state after the hanging lead 43 is partially removed.

With reference to FIGS. 8A and 8B, the hanging leads 43 are partially separated by pressing the hanging lead 43 from above. Here, portions of the respective hanging leads 43 each positioned in a corresponding one of the peripheral portions of the circuit board 11 are pressed from above by use of a pressing machine or the like. By this pressing, the hanging leads 43 are partially separated from the portions of the connection parts 42A and 42B. In this step, the land 45 attached to the back surface of the circuit board 11 is not separated from the circuit board 11.

With reference to FIG. 8C, with the above step, the portions of the respective hanging leads 43 each positioned in one of the peripheral portions of the circuit board 11 are removed, and the land 45 is separated from the lead frame 40. After this step, the lead frame 40 holds the circuit board 11 with the leads 25A mechanically connected to the circuit board 11 through the respective fixing parts 18.

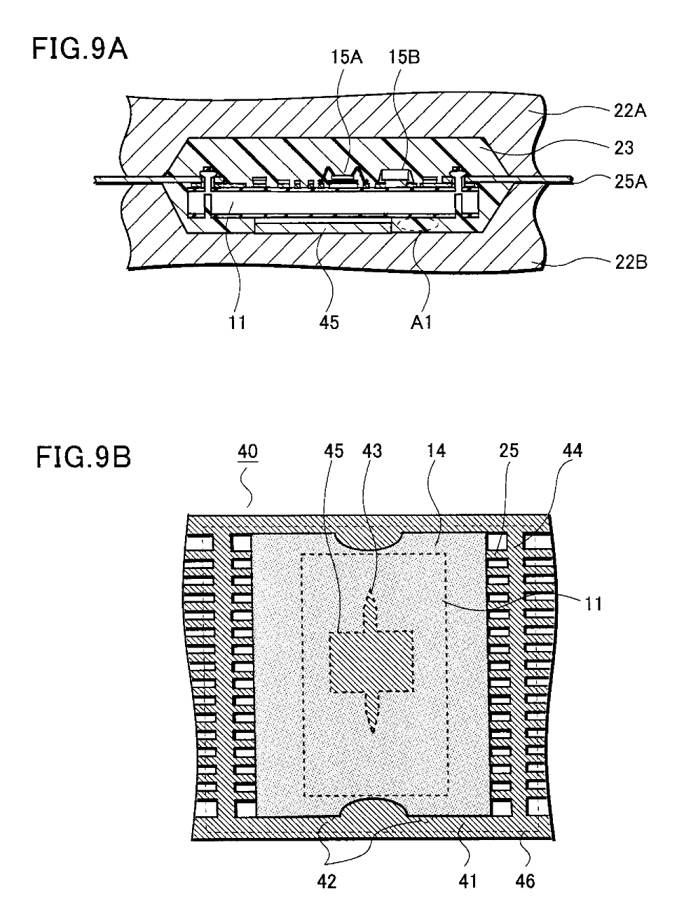

With reference to FIGS. 9A and 9B, a sealing resin 14 is next formed in a way that the circuit board 11 is covered with the sealing resin 14.

With reference to the cross-sectional view of FIG. 9A, molding is performed in a state where a back surface of the land 45 is caused to be in contact with an upper surface of a lower mold 22B. In the third embodiment, a position of the circuit board 11 inside a cavity 23 is fixed with the leads 25A. Thus, the circuit board 11 is prevented from being moved by the pressure of the resin injected into the cavity 23.

With reference to FIG. 9B, by separating each of the leads 25 at a part of regions where tie bars 44 are respectively provided, the hybrid integrated circuit device as described in the first embodiment is obtained. In the third embodiment, the portions of the respective hanging leads 43 each positioned in a corresponding one of the peripheral portions of the circuit board 11 are removed. Thus, short-circuiting between the circuit board 11 and the hanging leads 43 is prevented in a hybrid integrated circuit device to be manufactured. Specifically, with reference to FIG. 1B, insulation between a metal board 16 attached to the back surface of the circuit board 11 and the side faces of the circuit board 11 is secured.

### Fourth Embodiment

In this embodiment, descriptions will be provided for a structure of a hybrid integrated circuit device 10 as an example of a circuit device.

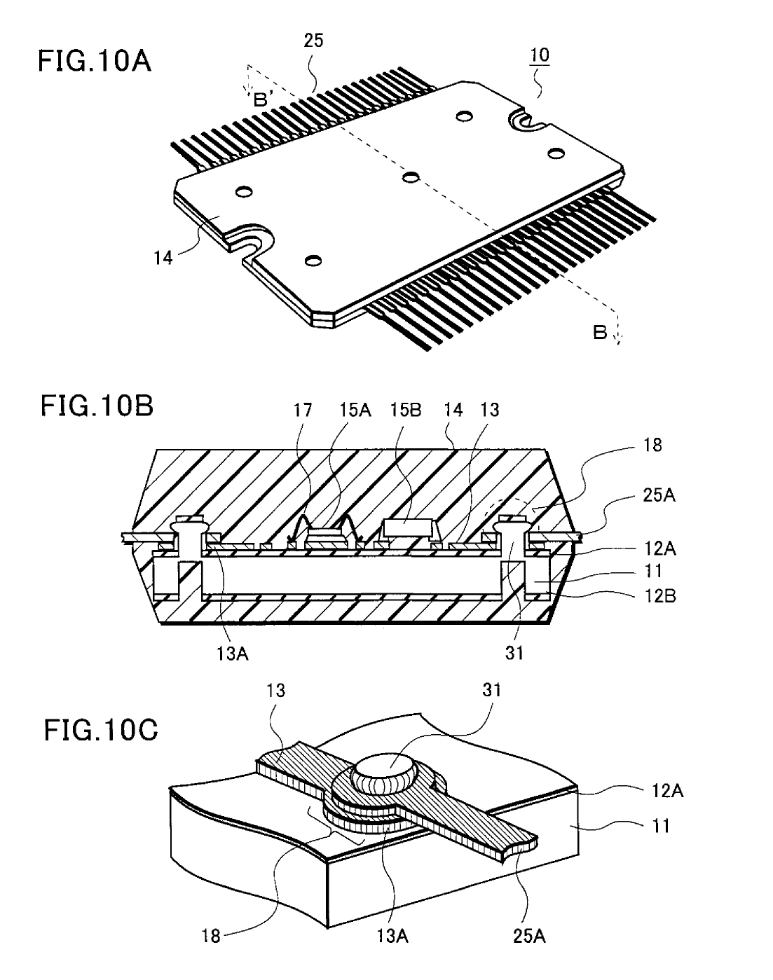

With reference to FIGS. 10A to 10C, descriptions will be provided for a configuration of the hybrid integrated circuit device 10 of the preferred embodiment of the present invention. FIG. 10A is a perspective view of the hybrid integrated circuit device 10 viewed from obliquely above. FIG. 10B is a cross-sectional view taken along the line B-B′ in FIG. 10A. FIG. 10C is a perspective view of a fixing part 18 in which one of leads 25A is fixed to a circuit board 11.

With reference to FIGS. 10A and 10B, on a surface of the rectangular circuit board 11, a first insulating layer 12A is formed. A semiconductor element 15A and a chip element 15B are electrically connected to predetermined spots in conductive patterns 13 formed on a surface of the first insulating layer 12A by use of solder or conductive paste. The conductive patterns 13, the semiconductor element 15A and the chip element 15B, which are formed on the surface of the circuit board 11, are covered with a sealing resin 14.

The circuit board 11 is a metal board mainly made of metal such as aluminum (Al) and copper (Cu). A specific size of the circuit board 11 is, for example, about 30 mm in length, 15 mm in width and 0.5 mm in thickness. Copper is suitable as a material of the circuit board 11. The circuit board 11 mainly made of copper has small warpage due to a temperature change or the like, and has sufficient mechanical strength even when the thickness thereof is as small as about 0.5 mm. In a case where a board made of aluminum is adopted as the circuit board 11, both principal surfaces of the circuit board 11 are subjected to alumite treatment.

The first insulating layer 12A is formed in a way that the first insulating layer 12A covers the entire upper surface of the circuit board 11. The first insulating layer 12A is made of an epoxy resin highly filled with fillers such as Al₂O₃, and the like. With the first insulating layer 12A, heat generated from the circuit elements included in the circuit device can be actively released to the outside through the circuit board 11. A specific thickness of the first insulating layer 12A is, for example, about 50 μm. The insulating layer 12A having this thickness can secure a breakdown voltage (insulation breakdown voltage) of 4 KV.

A second insulating layer 12B is formed in a way that the second insulating layer 12B covers a back surface of the circuit board 11. The second insulating layer 12B may have the same composition and thickness as those of the first insulating layer 12A. By covering the back surface of the circuit board 11 with the second insulating layer 12B, breakdown voltage characteristic of the back surface of the circuit board 11 can be secured. In this event, if insulation of the back surface of the circuit board 11 is not necessary, the hybrid integrated circuit device 10 may be configured without the second insulating layer 12B.

The conductive patterns 13 are made of metal such as copper, and are formed on the surface of the first insulating layer 12A so that a predetermined electric circuit is formed. Pads 13A respectively made of the conductive patterns 13 are formed on sides from which leads 25 are drawn out. Here, FIG. 10B shows the single-layer conductive patterns 13. However, multilayer conductive patterns 13 each including layers superposed with insulating layers interposed between each layer may be formed on the upper surface of the circuit board 11.

The pads 13A are respectively made of the conductive patterns 13, and are parts electrically connected to the respective leads 25. In this event, with reference to FIG. 10B, the ring-shaped pads 13A are formed in a way that protrusions 31 provided to the circuit board 11 are surrounded by the respective pads 13A. The pads 13A, to which thin metal wires (not shown) are respectively connected, are formed to have a rectangular shape.

The circuit elements including the semiconductor element 15A and the chip element 15B are fixed to the predetermined spots in the conductive patterns 13. A transistor, an LSI chip, a diode or the like is adopted as the semiconductor element 15A. Here, the semiconductor element 15A and the conductive patterns 13 are connected to each other through thin metal wires 17. An element, such as a chip resistor, a chip capacitor, an inductance, a thermistor, an antenna and an oscillator, which has electrode parts respectively at both ends thereof is adopted as the chip element 15B. Furthermore, as the circuit element. a resin-sealed package and the like can also be fixed to the conductive patterns 13.

One end of each of the leads 25 is electrically connected to a corresponding one of the pads 13A on the circuit board 11, and the other end thereof is drawn out to the outside from the sealing resin 14. The leads 25 are made of metal mainly made of copper (Cu), aluminum (Al), Fe—Ni alloy or the like,

In this event, the leads 25 are connected to the pads 13A provided along two opposite sides of the circuit board 11. However, the pads 13A may be provided along one side or four sides of the circuit board 11, and the leads 25 may be connected to the respective pads 13A.

The sealing resin 14 is formed by transfer molding using a thermosetting resin or by injection molding using a thermoplastic resin. In FIG. 10B, the conductive patterns 13, the semiconductor element 15A, the chip element 15B and the thin metal wires 17 are sealed with the sealing resin 14. In FIG. 10B, the entire circuit board 11 including the back surface thereof is covered with the sealing resin 14. However, the back surface of the circuit board 11 may be exposed from the sealing resin 14.

With reference to FIGS. 10B and 10C, descriptions will be provided for the fixing parts 18 in each of which one of the leads 25A is connected to the circuit board 11. In each of the fixing parts 18, by caulking the lead 25A to the protrusion 31, the lead 25A is connected to the circuit board 11.

The protrusions 31 are formed by subjecting the circuit board 11 to half blanking processing from the back surface of the circuit board 11 so that the circuit board 11 is caused to partially protrude upward. Ring-shaped tips of the leads 25A are placed on the circuit board 11 in a way that the protrusions 31 are surrounded by the respective tips of the leads 25A. The ring-shaped tips of the leads 25A are respectively caulked by pressure-deformed upper parts of the protrusions 31. In order to achieve more secure connection between the protrusions 31 and the respective leads 25A, a conductive material such as solder may be applied to the fixing part 18. The protrusion 31 may have a cylindrical shape or a prismatic shape.

In each of the fixing part 18, the lead 25A is electrically connected to the protrusion 31. Specifically, metal is exposed on a side face of the protrusion 31 formed by blanking processing. Accordingly, by causing each of the leads 25A to be in contact with a corresponding one of the side faces of the protrusions 31, the leads 25A are electrically connected to the respective protrusions 31. Moreover, since the protrusions 31 are parts of the circuit board 11, the leads 25A and the circuit board 11 are electrically connected to each other by use of the configuration described above. As described above, by applying a conductive adhesive, such as solder, to a connection part between each of the protrusions 31 and a corresponding one of the leads 25A, reliability of electrical connection between the protrusions 31 and the respective leads 25A can be improved.

In each of the fixing parts 18, the back surface of the lead 25A is in contact with the upper surface of the pad 13A, and the lead 25A and the pad 13A are electrically connected to each other. Thereby, in each of the fixing parts 18, the conductive patterns 13, the lead 25A and the circuit board 11 are electrically connected to one another.

In the fourth embodiment, by use of the fixing parts 18, the circuit board 11 and the conductive patterns 13 can be set to have the same potential (for example, a ground potential or a power supply potential). Hence, a parasitic capacity generated between the circuit board 11 and the conductive patterns 13 can be reduced. Thus, operations of the electric circuit formed on the surface of the circuit board 11 can be stabilized. Furthermore, by fixing the circuit board 11 to the ground potential, a shield effect of the circuit board 11 can also be improved.

In the fourth embodiment, the leads 25A are mechanically fixed to the respective protrusions 31 in the circuit board 11. Thereby, compared with the connection structure of the background art using the conductive adhesive, the leads 25A can be firmly fixed to the circuit board 11.

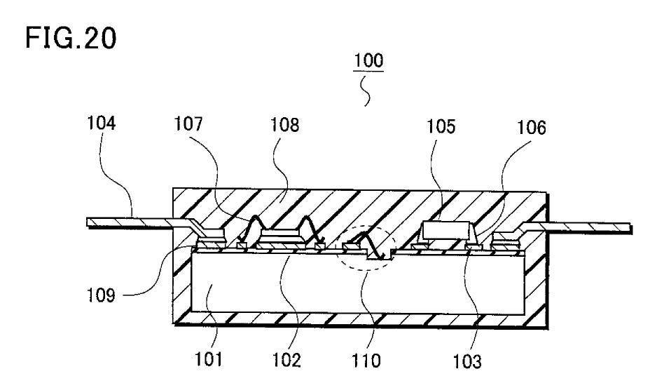

Moreover, the conductive patterns 13 and the circuit board 11 are electrically connected to each other by the fixing parts 18. Thereby, it is not necessary to additionally form a substrate connection part 110 (see FIG. 20) as described in the section of the background art. Moreover, the conductive patterns extended to the substrate connection part 110 are also no longer needed.

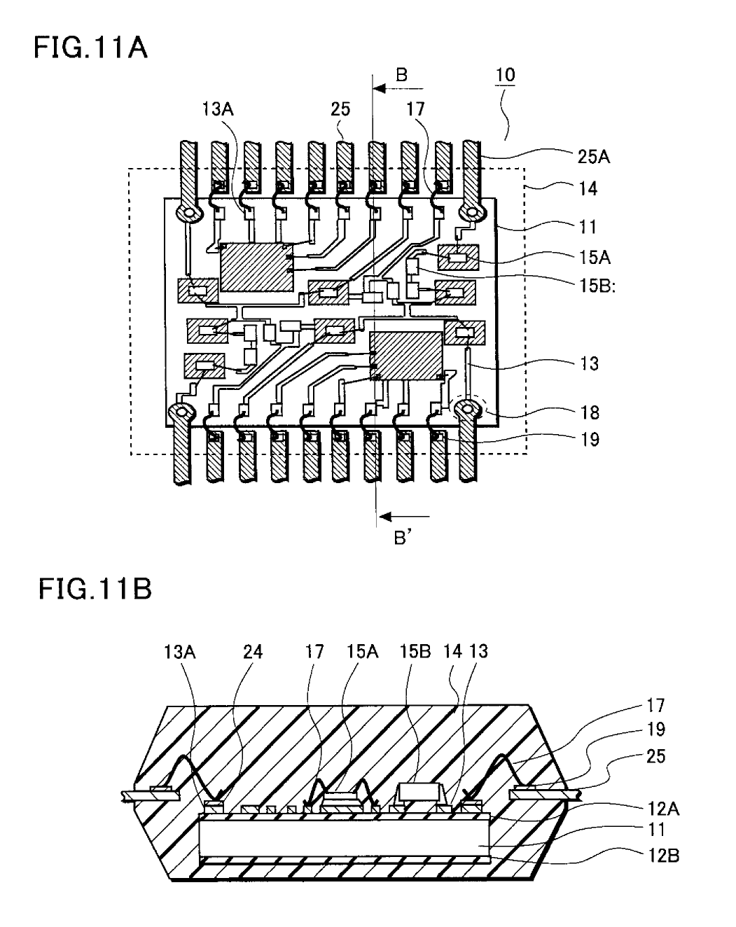

With reference to FIGS. 11A and 11B, the configuration of the hybrid integrated circuit device 10 will be further described. FIG. 11A is a plan view showing the electric circuit formed on the surface of the circuit board 11. FIG. 11B is a cross-sectional view taken along the line B-B′ in FIG. 11A.

With reference to FIG. 11A, on the upper surface of the circuit board 11, a plurality of the pads 13A are formed along opposite sides of the circuit board 11. The pads 13A which are positioned at four corners (not shown) are directly connected to the respective leads 25A by use of the fixing parts 18. The other pads 13A are respectively connected to the leads 25 through the thin metal wires 17.

Here, each of the leads 25A, which is fixed with a corresponding one of the fixing parts 18, are respectively provided at four spots on the circuit board 11. However, the number of leads 25A can be arbitrarily changed. For example, if it is intended to electrically connect the circuit board 11 to the leads 25A, at least one lead 25A may be provided through the fixing part 18. Furthermore, if it is intended to mechanically support the circuit board 11 in the manufacturing steps, at least two leads 25A may be fixed to the circuit board 11 by use of the respective fixing parts 18.

With reference to FIG. 11B, the pads 13A provided on the circuit board 11 are connected to the respective leads 25 by use of the thin metal wires 17 made of gold (Au) with a diameter of about 30 μm. In order to perform wire bonding of the thin metal wires 17 made of gold (Au), the upper surfaces of the pads 13A are respectively covered with plated films 24 made of gold (Au). Moreover, the upper surfaces of the leads 25 are also partially covered with the respective plated films 19 made of gold (Au). Here, in a case where a large current capacity is needed, aluminum (Al) wires with a diameter of 150 μm or more may be used as the thin metal wires 17.

By electrically connecting the pads 13A on the circuit board 11 to the respective leads 25 by use of the thin metal wires 17, a number of pads 13A can be disposed along one side of the circuit board 11. This is because a planar size of the pad 13A can be reduced within a range in which wire bonding of the thin metal wires 17 is possible. Meanwhile, in the background art, relatively large pads are needed since the back surfaces of the leads are fixed to the respective pads by use of the conductive adhesive. Specifically in the background art, the planar size of the pad is 1 mm×1 mm. On the other hand, in the fourth embodiment, the planar size of each of the pads 13A is, for example, about 200 μm×200 μm. Since the individual pads 13A can be miniaturized, a number of pads 13A can be provided along the sides of the circuit board 11.

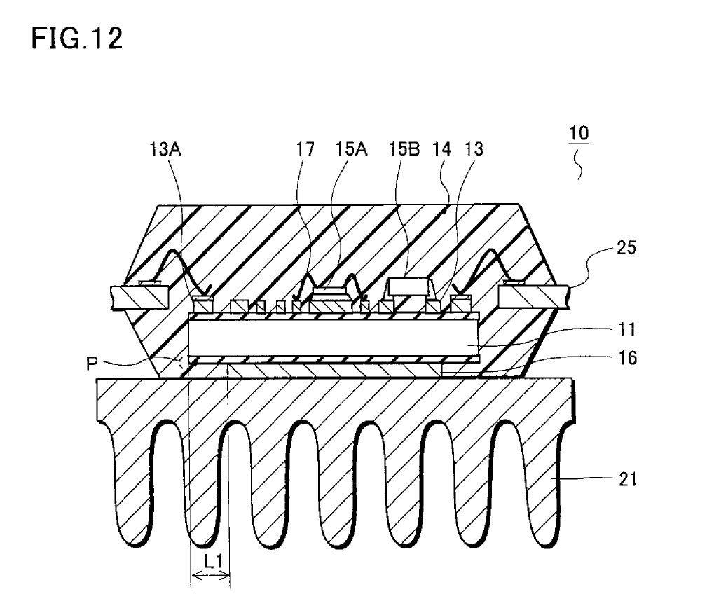

Subsequently, with reference to FIG. 12, descriptions will be provided for a configuration in which a radiation fin 21 is attached to the hybrid integrated circuit device 10.

In this event, in order to improve heat release properties of the hybrid integrated circuit device 10, the radiation fin 21 is attached to the back surface of the hybrid integrated circuit device 10. By attaching the radiation fin 21, which is made of a material excellent in thermal conductivity, such as copper and aluminum, to the hybrid integrated circuit device 10, heat generated in the hybrid integrated circuit device 10 can be actively released to the outside. In order to improve a heat release effect, a metal board 16 attached to the back surface of the circuit board 11 is exposed to the outside from the lower surface of the sealing resin 14, and is attached to an upper surface of the radiation fin 21.

By providing the metal board 16, which is exposed to the outside, on the back surface of the circuit board 11, the heat release properties of the entire device can be improved. However, in a case of such a configuration, it is necessary to prevent short-circuiting of the circuit board 11. Hence, in the fourth embodiment, each of edges P of the circuit board 11 and the metal board 16 are separated from each other so that short-circuiting is avoided therebetween. A distance L1, for which each of the edges P of the circuit board 11 and the metal board 16 are separated from each other, is preferably about 2 mm to 3 mm or more. Accordingly, a withstand voltage between each of the edges P and the metal board 16 is secured. Metal is exposed on the edges P, which are respectively on the side faces of the circuit board 11. Thus, for example, even if the circuit board 11 fixed to the ground potential and the radiation fin 21 have different potentials, the circuit board 11 and the radiation fin 21 are not short-circuited.

### Fifth Embodiment

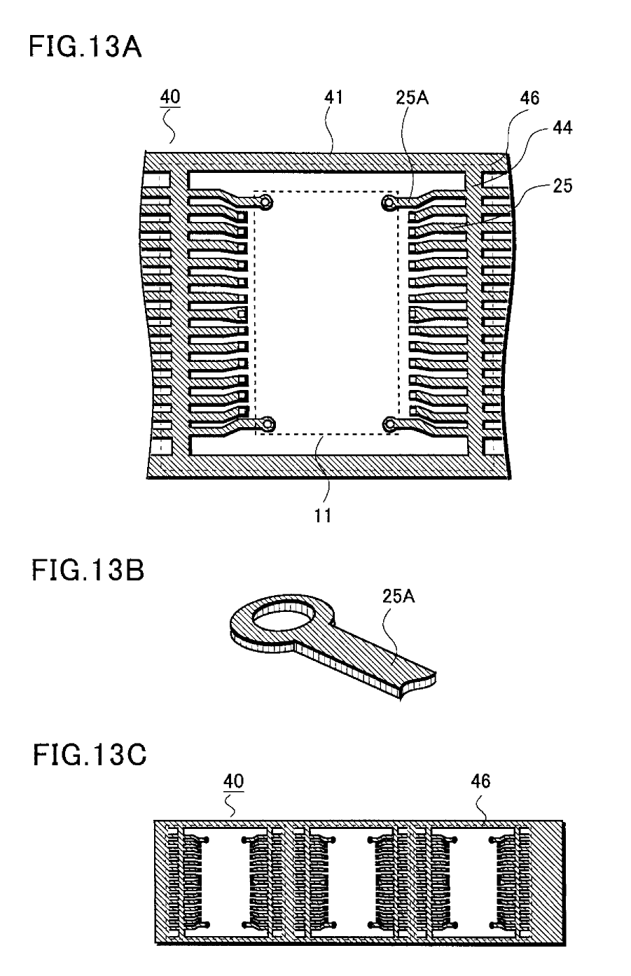

In this embodiment, with reference to FIGS. 13 to 15, descriptions will be provided for a method of manufacturing a hybrid integrated circuit device 10. In the manufacturing method of this embodiment, the hybrid integrated circuit device 10 is manufactured by using a lead frame 40 in which a number of leads 25 are provided. Moreover, in the middle of manufacturing steps, the lead frame 40 holds the circuit board 11 by mechanically connecting the leads 25A to a circuit board 11.

With reference to FIGS. 13A to 13C, first, the lead frame 40, in which a number of leads 25 are provided, is prepared. FIG. 13A is a plan view showing one of units 46 provided to the lead frame 40. FIG. 13B is a perspective view showing a tip of one of the leads 25A. FIG. 13C is a plan view showing the entire lead frame 40. In FIGS. 13A to 13C, the circuit board 11 to be mounted is indicated by a dotted line.

With reference to FIG. 13A, the unit 46 includes a number of leads 25 each having one of ends thereof positioned close to a region on which the circuit board 11 is mounted. In the page space for FIG. 13A, the leads 25 are horizontally extended from both of right and left sides of the unit 46 toward the region on which the circuit board 11 is mounted. The plurality of leads 25 are connected to one another with tie bars 44 extended from an outer frame 41. Thus, deformation of the leads is prevented. Moreover, plated films are formed on portions of upper surfaces of the respective leads 25 to which thin metal wires are connected in a subsequent step. Tips of the leads 25A, which are provided in a way that the positions of the tips respectively correspond to four corners of the circuit board 11, are extended to reach inside the region on which the circuit board 11 is mounted.

With reference to FIG. 13B, the tips of the respective leads 25A at the four corners of the circuit board 11 are formed into a ring shape. The ring-shaped tips of the leads 25A are mechanically and electrically connected to the circuit board 11 in a subsequent step.

With reference to FIG. 13C, in the strip-shaped lead frame 40, the plurality of units 46 having the configuration as described above are disposed with a space between each of the units 46. In the fifth embodiment, the hybrid integrated circuit device is manufactured by providing the plurality of units 46 in the lead frame 40. Hence, wire bonding, a molding step and the like are collectively performed to improve productivity.

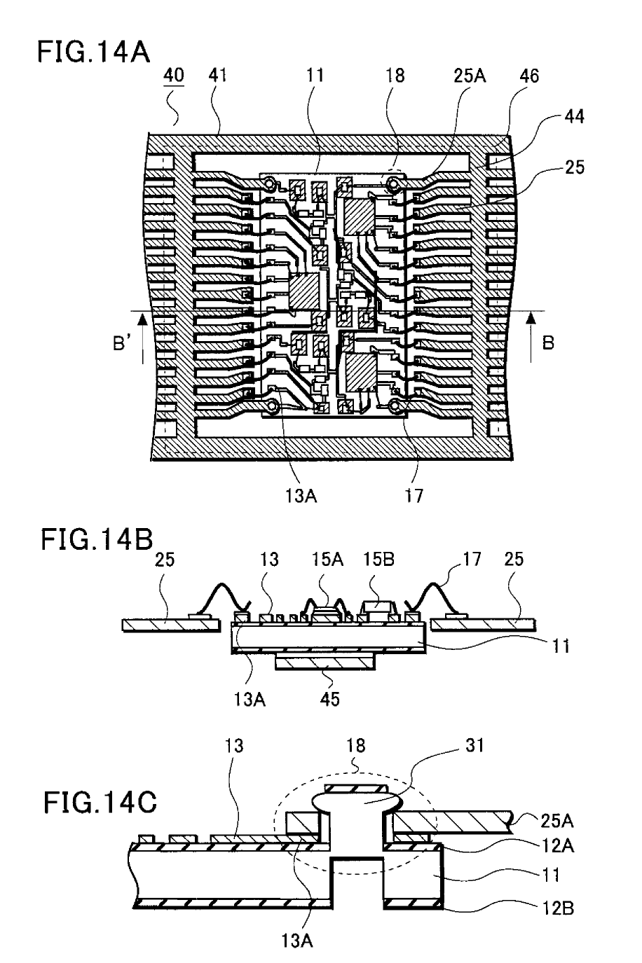

With reference to FIGS. 14A to 14C, the leads 25 in each of the units 46 are subsequently connected to the circuit board 11. FIG. 14A is a plan view of one of the units 46 on which the circuit board 11 is mounted. FIG. 14B is a cross-sectional view taken along the line B-B′ in FIG. 14A. FIG. 14C is a cross-sectional view of a portion in which the lead 25A is connected to the circuit board 11. In this step, conductive patterns 13, a semiconductor element 15A, a chip element 15B and protrusions 31 are previously formed on the front surface of the circuit board 11.

With reference to FIGS. 14A and 14B, pads 13A on the circuit board 11 are respectively connected to the leads 25 by use of thin metal wires 17. Since the upper surfaces of the pads 13A and the upper surfaces of the leads 25 are covered with plated films made of gold (Au) or the like, gold wires made of gold (Au) can be used as the thin metal wires 17. By adopting gold as a material of the thin metal wires 17, time required for wire bonding can be shortened. Accordingly, the productivity can be improved. Moreover, the circuit elements arranged on the circuit board 11 and the leads 25 can be directly connected to each other by use of the thin metal wires 17.

In this step, near the four corners of the circuit board 11, the tips of the leads 25A are fixed to the circuit board 11 by use of respective fixing parts 18. By fixing the leads 25A to the circuit board 11, the circuit board 11 is held by the lead frame 40. Here, the number of leads 25A mechanically fixed to the circuit board 11 need not be four. At least two or more number of the leads 25A may be connected to the circuit board 11.

With reference to FIG. 14C, in this step, the leads 25A are mechanically fixed to the circuit board 11 by caulking the leads 25A to the respective protrusions 31 obtained by causing the circuit board 11 to protrude in its thickness direction. Specifically, a ring-shaped tip of the lead 25A is first placed on the upper surface of the circuit board 11 in a way that the tip surrounds the protrusion 31. Next, the tip of the lead 25A is caulked to the protrusion 31 by pressure-deforming an upper part of the protrusion 31 by use of a pressing machine or the like. In order to improve bonding strength between each of the leads 25A and the circuit board 11, a conductive adhesive such as solder may be applied to each of connection parts between the lead 25A and the circuit board 11. In this step, the lead 25A and the circuit board 11 are also electrically connected to each other by use of the protrusion 31. Moreover, by connecting the back surface of the lead 25A to the upper surface of the pad 13A, the lead 25A is electrically connected to one of the conductive patterns 13.

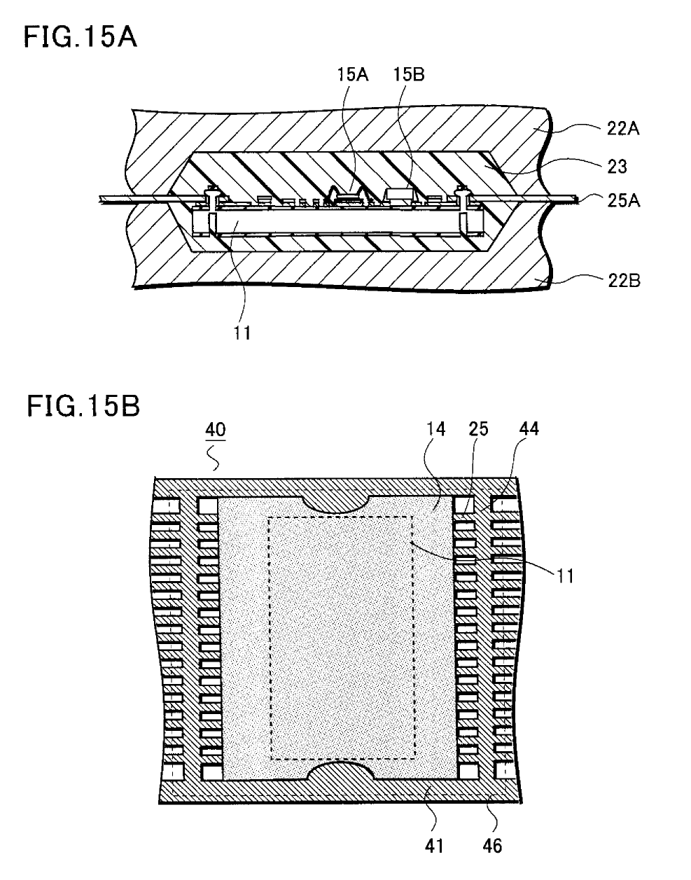

With reference to FIGS. 15A and 15B, a sealing resin is subsequently formed in a way that the sealing resin covers the circuit board 11. FIG. 15A is a cross-sectional view showing a step of molding the circuit board 11 by use of a mold. FIG. 15B is a plan view showing the lead frame 40 in a state after the molding is performed.

With reference to FIG. 15A, the circuit board 11 is first housed in a cavity 23 formed with an upper mold 22A and a lower mold 22B. Here, by causing the upper and lower molds 22A and 22B to be in contact with the leads 25A, a position of the circuit board 11 inside the cavity 23 is fixed. Subsequently, by injecting a resin into the cavity 23 through a gate (not shown) provided to the mold, the circuit board 11 is sealed. In this step, transfer molding using a thermosetting resin or injection molding using a thermoplastic resin is performed.

With reference to FIG. 15B, after the molding step described above is completed, the leads 25 are separated from the lead frame 40. The leads 25 are separated at the spots where one of the tie bars 44 are provided, and the hybrid integrated circuit device as shown in FIGS. 1A and 1B is separated from the lead frame 40.

### Sixth Embodiment

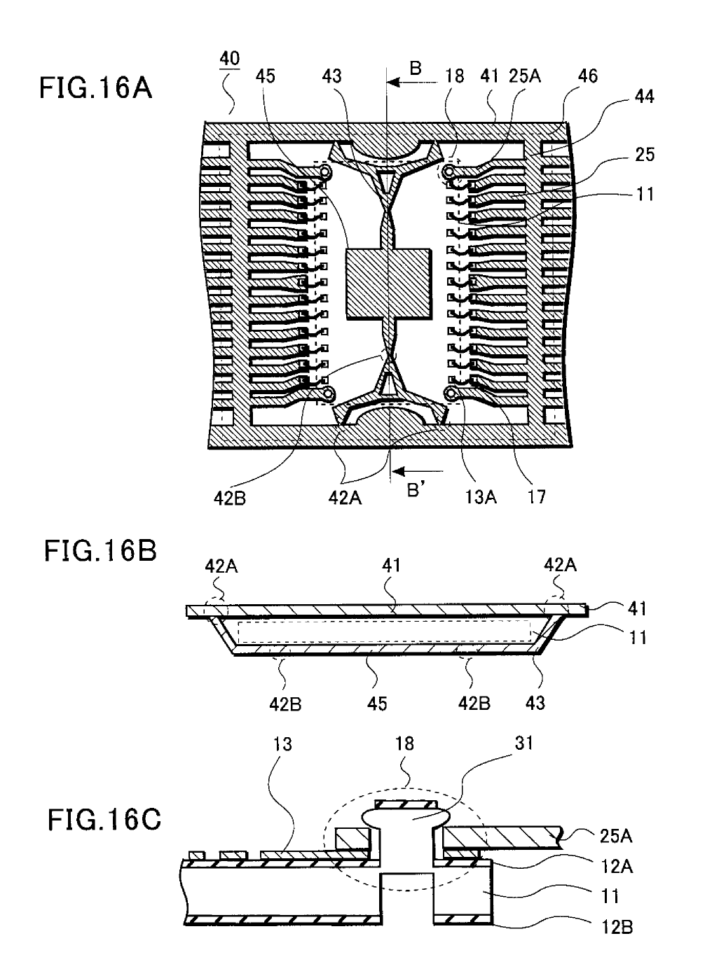

In this embodiment, with reference to FIGS. 16 to 18, descriptions will be provided for another method of manufacturing a hybrid integrated circuit device 10. This embodiment is basically the same as the second embodiment described above, and is different from the second embodiment in that lands 45 are provided to a lead frame 40. Each of the lands 45 is attached to the back surface of the circuit board 11. By attaching the land 45 to the back surface of the circuit board 11, occurrence of voids below the circuit board 11 is suppressed in a step of forming a sealing resin. Furthermore, it is made possible to manufacture the hybrid integrated circuit device 10 as shown in FIG. 12, in which a metal board 16 (the land 45) exposed to the outside is formed on the back surface of the circuit board 11.

With reference to FIGS. 16A to 16C, the circuit board 11 is first fixed to the lead frame 40, and pads 13A on the circuit board 11 are connected to the respective leads 25. FIG. 16A is a plan view of the lead frame 40. FIG. 16B is a cross-sectional view taken along the line B-B′ in FIG. 16A. FIG. 16C is a cross-sectional view showing a configuration of one of fixing parts 18 for fixing the circuit board 11.

With reference to FIGS. 16A and 16B, in the sixth embodiment, each of units 46 includes a number of leads 25 each having one of ends thereof positioned close to a region on which the circuit board 11 is mounted; and the land 45 connected to an outer frame 41 of the lead frame 40 by use of hanging leads 43. As in the case of the fifth embodiment, four leads 25A are provided in a manner that the four leads respectively correspond to four corners of the circuit board 11.

The land 45 is formed inside the region on which the circuit board 11 is mounted, and the circuit board 11 is mounted on an upper surface of the land 45. The land 45 is connected to the outer frame 41 of the lead frame 40 by the hanging leads 43 extended in a vertical direction in the page space for FIG. 16A. The land 45 also has a function of improving heat release properties of the entire device by remaining on the back surface of the circuit board 11.

Connection parts 42A and 42B are provided to each of the hanging leads 43. Thereby, the hanging leads 43 respectively positioned in the peripheral portions of the circuit board 11 can be separated from the lead frame 40. Specifically, the connection parts 42A are respectively provided to portions where the hanging leads 43 and the outer frame 41 are continuous with each other. Moreover, the other connection parts 42B are each provided to intermediate portions of the corresponding one of the hanging leads 43. The connection parts 42A and 42B are formed to be narrow in width. Thus, the hanging leads 43 can be partially removed. By removing the hanging leads 43 respectively positioned in the peripheral portions of the circuit board 11, short-circuiting between the hanging leads 43 and the circuit board 11 is prevented.

In this step, the circuit board 11 is fixed to the upper surface of the land 45 having the configuration as described above. The pads 13A on the circuit board 11 are connected to the respective leads 25 through thin metal wires 17. Furthermore, the leads 25A are respectively fixed to protrusions 31 in the circuit board 11.

With reference to the cross-sectional view of FIG. 16B, the land 45 is positioned below the outer frame 41 with the hanging leads 43 bent downward. Thereby, the circuit elements and the like which are mounted on the upper surface of the circuit board 11 can be positioned in the vicinity of the center of the device in its thickness direction. Accordingly, even in a case where an external factor, such as a temperature change, causes bending stress to act on the entire device, the stress acting on the circuit elements can be reduced. Thus, connection reliability of the circuit elements can be improved.

With reference to FIG. 16C, in each of the fixing parts 18, the protrusion 31, which is provided by causing the circuit board 11 to partially protrude, is used to caulk a ring-shaped tip of the lead 25A. A specific configuration of the fixing part 18 is the same as that in the fifth embodiment.

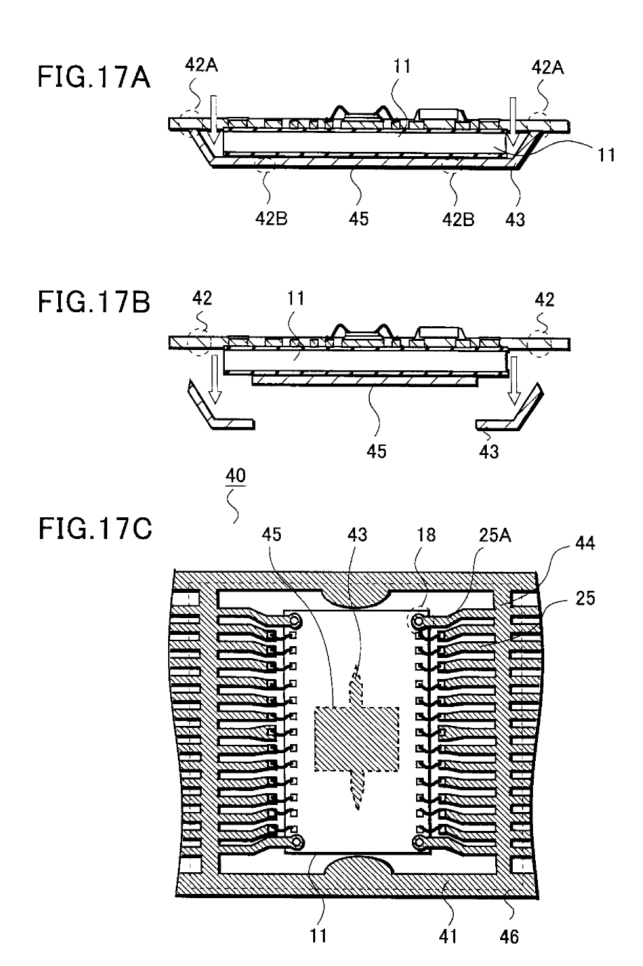

With reference to FIGS. 17A to 17C, subsequently, the hanging leads 43 respectively positioned in the peripheral portions of the circuit board 11 are separated from the lead frame 40. FIGS. 17A and 17B are cross-sectional views showing a state where the hanging leads 43 are partially separated. FIG. 17C is a plan view of the lead frame 40 in a state after the hanging lead 43 is partially removed.

With reference to FIGS. 17A and 17B, the hanging leads 43 are partially separated by pressing the hanging leads 43 from above. Here, the portions of the hanging leads 43 respectively positioned in the peripheral portions of the circuit board 11 are pressed from above by use of a pressing machine or the like. By this pressing, the hanging leads 43 are partially separated from the portions of the connection parts 42A and 42B. In this step, the land 45 attached to the back surface of the circuit board 11 is not separated from the circuit board 11.

With reference to FIG. 17C, by the above step, the portions of the hanging leads 43 respectively positioned in the peripheral portions of the circuit board 11 are removed, and the land 45 is separated from the lead frame 40. After this step, the lead frame 40 holds the circuit board 11 with the leads 25A mechanically connected to the circuit board 11 through the respective fixing parts 18.

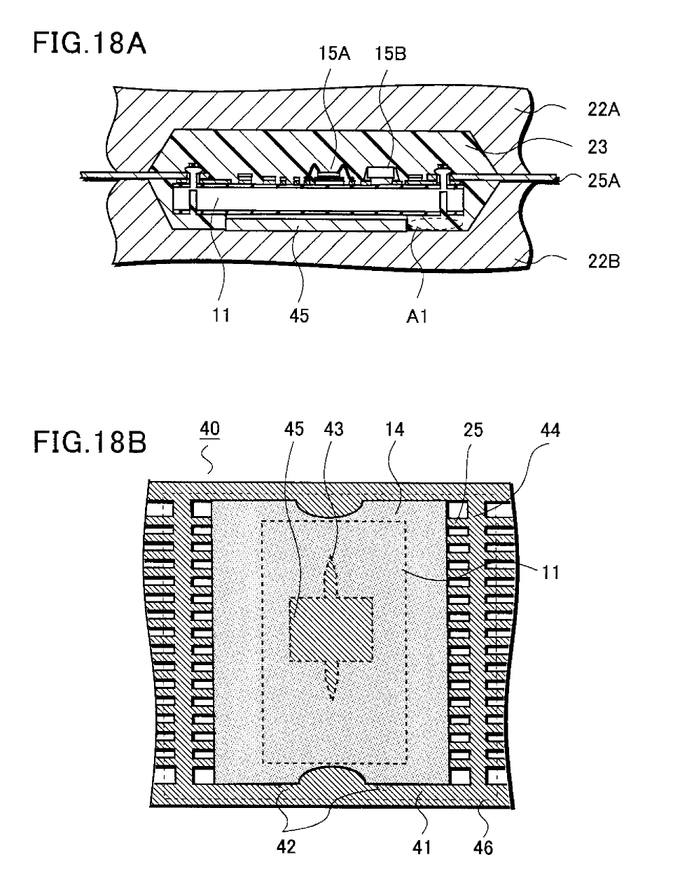

With reference to FIGS. 18A and 18B, a sealing resin 14 is subsequently formed in a way that the sealing resin 14 covers the circuit board 11.

With reference to the cross-sectional view of FIG. 18A, molding is performed in a state where a back surface of the land 45 is caused to be in contact with an upper surface of a lower mold 22B. In this step, a position of the circuit board 11 inside a cavity 23 is fixed by use of the leads 25A. Thereby, the circuit board 11 is prevented from being moved by the pressure of the resin injected into the cavity 23.

In the sixth embodiment, since a region in the center of the back surface of the circuit board 11 is covered with the land 45, it is not necessary to apply the sealing resin to the region. Accordingly, it suffices that the sealing resin be applied only to a region A1 below the peripheral portion of the circuit board 11. Hence, it is made possible to prevent occurrence of voids not filled with the sealing resin.

With reference to FIG. 18B, by separating each of the leads 25 at a part of regions where tie bars 44 are respectively provided, the hybrid integrated circuit device as described in the first embodiment is obtained. In the sixth embodiment, the portions of the hanging leads 43 respectively positioned in the peripheral portions of the circuit board 11 are removed. Thus, short-circuiting between the circuit board 11 and the hanging leads 43 is prevented in a hybrid integrated circuit device to be manufactured. Specifically, with reference to FIG. 12, insulation between the metal board 16 attached to the back surface of the circuit board 11 and the side faces of the circuit board 11 is secured.

According to the preferred embodiment of the present invention, since a metal board is attached to the back surface of the circuit device, heat release properties for heat generated from the circuit elements included in the circuit device can be improved. Moreover, the sealing resin covers peripheral portions respectively of the surface, side faces and the back surface of the circuit board in a way that the metal board is exposed. Accordingly, the sealing resin causes an anchor effect by which bonding strength is improved between the sealing resin and the circuit board. Moreover, since the peripheral portion of the back surface of the circuit board is also covered with the sealing resin, moisture resistance is also improved.

According to the preferred embodiment of the present invention, since the pads on the circuit board and the respective leads are connected to each other with the thin metal wires, a size of each pad can be set smaller than that of a conventional one. Moreover, more pads can be formed on the circuit board.

According to the method of manufacturing a circuit device of the preferred embodiment of the present invention, the lead frame including the land and the leads is prepared. After the circuit board is fixed to the surface of the land, the pads on the circuit board and the leads are respectively connected to each other with the thin metal wires. Thereby, in the middle of the manufacturing steps, the circuit board is mechanically supported by the land, and it is not necessary to support the circuit board with the leads. Thus, the pads on the circuit board and the respective leads can be connected to each other by wire bonding having low mechanical strength.

According to the method of manufacturing a circuit device of the preferred embodiment of the present invention, the circuit board is mounted on the land connected to the outer frame by use of the hanging leads, and the pads on the circuit board and the leads are respectively connected to each other. Thereafter, portions of the respective hanging leads positioned in the peripheral portions of the circuit board are removed. Thus, since the hanging leads respectively positioned in the peripheral portions of the circuit board are removed, short-circuiting between the circuit board and the hanging leads is prevented. Moreover, by mechanically connecting at least two of the leads to the circuit board, the circuit board and the lead frame can be maintained in a connected state even after the portions of the hanging leads are removed.

According to the preferred embodiment of the present invention, the leads can be fixed to the circuit board by caulking the leads to the respective protrusions obtained by causing the circuit board to partially protrude. Accordingly, bonding strength between the leads and the circuit board is quite strong. Thus, the leads are prevented from being detached from the circuit board.

The circuit board can be connected to the ground potential through the protrusions. Thus, it is not necessary to additionally provide a substrate connection part as described above. Moreover, it is not necessary to extend one of the conductive patterns to the substrate connection part. Thus, it is made possible to simplify the configuration of the conductive patterns formed on the surface of the circuit board.

According to the method of manufacturing a circuit device of the preferred embodiment of the present invention, the leads and the circuit board can be mechanically bonded to each other by caulking the leads respectively to the protrusions obtained by causing the circuit board to partially protrude. Thus, in a case where a circuit device is manufactured by use of a lead frame with a number of leads formed therein, the circuit board can be fixed to the lead frame by use of the leads respectively caulked to the protrusions in the circuit board. Accordingly, since it is not necessary to additionally form a device for connecting the circuit board to the lead frame, the configuration of the lead frame can be simplified.

What is claimed is:

1. A circuit device comprising:
a circuit board on a front surface of which conductive patterns, pads respectively made of the conductive patterns and circuit elements connected to the conductive patterns are formed;
a metal board attached to a back surface of the circuit board;
a sealing resin which covers at least the front surface, side faces and peripheral portions of the back surface of the circuit board in a state where a back surface of the metal board is exposed to the outside; and
leads which are respectively connected to the pads through thin metal wires, and each of which has one end drawn out from the sealing resin,

2. The circuit device according to claim 1, wherein the circuit board and the metal board are insulated from each other by use of an insulating material.

3. The circuit device according to claim 1, wherein the circuit board is a metal board mainly made of copper.

4. The circuit device according to claim 1, wherein the pads positioned at edges of the circuit board are mechanically bonded to the respective leads.

5. The circuit device according to claim 1, wherein
protrusions are formed by causing the circuit board to partially protrude, and
the leads are mechanically bonded to the circuit board by caulking the leads to the respective protrusions.

6. A method of manufacturing a circuit device comprising the steps of.
preparing a lead frame which includes a land connected to an outer frame with hanging leads and a plurality of leads each having one of ends thereof disposed in a way that the land is surrounded by the ends of the lands;
mounting, on the land, a circuit board on a front surface of which conductive patterns, pads respectively made of the conductive patterns and circuit elements connected to the conductive patterns are formed;
electrically connecting the pads on the circuit board to the respective leads by use of thin metal wires; and
forming a sealing resin in a way that the sealing resin covers portions of the respective leads connected to the thin metal wires, the circuit board and the thin metal wires.

7. The method of manufacturing a circuit device according to claim 6, wherein
the land is formed to be smaller than the circuit board,
the back surface of the circuit board, which is not covered with the land, is covered with the sealing resin, and
a back surface of the land is exposed to the outside through the sealing resin.

8. The method of manufacturing a circuit device according to claim 6, wherein the circuit element mounted on the circuit board and the lead is directly connected to each other by use of the thin metal wire.

9. A method of manufacturing a circuit device comprising the steps of:
preparing a lead frame which includes a land connected to an outer frame with hanging leads and a plurality of leads each having one of ends thereof disposed in a way that the land is surrounded by the ends of the lands;
mounting, on the land, a circuit board on a front surface of which conductive patterns, pads respectively made of the conductive patterns and circuit elements connected to the conductive patterns are formed;
electrically connecting the pads on the circuit board to the respective leads by use of thin metal wires, and mechanically bonding at least two of the leads to the circuit board;
partially removing the hanging leads in regions respectively corresponding to peripheral portions of the circuit board; and
forming a sealing resin in a way that the sealing resin covers portions of the respective leads connected to the thin metal wires, the circuit board and the thin metal wires.

10. The method of manufacturing a circuit device according to claim 9, wherein, in a step after the hanging leads are partially removed, the circuit board is supported with the leads mechanically bonded to the circuit board.

11. The method of manufacturing a circuit device according to claim 9, wherein
the land is formed to be smaller than the circuit board,
a back surface of the circuit board, which is not covered with the land, is covered with the sealing resin, and
a back surface of the land is exposed to the outside through the sealing resin.

12. The method of manufacturing a circuit device according to claim 9, wherein the circuit elements mounted on the circuit board and the respective leads are directly connected to each other by use of the thin metal wires.

13. The method of manufacturing a circuit device according to claim 9, wherein
protrusions are formed by causing the circuit board to partially protrude, and
the leads are mechanically bonded to the circuit board by caulking the leads to the respective protrusions.

14. A circuit device comprising:
a circuit board which is made of a conductive material, and which has a surface thereof covered with an insulating layer;
conductive patterns formed on a front surface of the insulating layer;
circuit elements electrically connected to the conductive patterns; and
leads respectively connected to pads each made of one of the conductive patterns,
the circuit device wherein at least one of the leads is connected to a corresponding one of protrusions obtained by causing the circuit board to partially protrude in its thickness direction.

15. The circuit device according to claim 14, wherein a ring-shaped tip of the lead is caulked to the protrusion.

16. The circuit device according to claim 14, wherein the circuit board is connected to a ground potential through the protrusion.

17. The circuit device according to claim 14, wherein the lead connected to the protrusion is connected to a corresponding one of the conductive patterns.

18. The circuit device according to claim 14, wherein the conductive material is applied to a connection part between the protrusion and the lead.

19. A method of manufacturing a circuit device comprising the steps of:
forming an electric circuit including conductive patterns and circuit elements on a front surface of a circuit board made of a conductive material;
fixing each of leads to a corresponding one of pads respectively made of the conductive patterns; and
electrically connecting at least one of the leads to the circuit board,
the method wherein
protrusions, which are obtained by causing the circuit board to partially protrude in its thickness direction, are provided, and
the leads are connected to the circuit board by caulking the leads to the respective protrusions.

20. A method of manufacturing a circuit device comprising the steps of:
preparing a lead frame including a plurality of leads disposed in a way that a region, on which a circuit board is mounted, is surrounded by the leads;
preparing the circuit board on a front surface of which conductive patterns, pads respectively made of the conductive patterns and circuit elements connected to the conductive patterns are formed, and in which protrusions protruding in the thickness direction of the circuit board are provided;
fixing the circuit board to the lead frame by caulking at least two of the leads respectively to corresponding ones of the protrusions in the circuit board, and electrically connecting the pads on the circuit board to the respective leads; and
sealing at least the front surface of the circuit board with a sealing resin in a state where the circuit board is fixed to the lead frame by use of the protrusions.

21. A method of manufacturing a circuit device comprising the steps of:
preparing a lead frame which includes a land connected to an outer frame with hanging leads and a plurality of leads each having one of ends thereof disposed in a way that the land is surrounded by the ends of the lands;
mounting, on the land, a circuit board on a front surface of which conductive patterns, pads respectively made of the conductive patterns and circuit elements connected to the conductive patterns are formed;
caulking at least two of the leads respectively to protrusions provided by causing the circuit board to partially protrude in its thickness direction;
partially removing the hanging leads in regions respectively corresponding to peripheral portions of the circuit board; and
sealing at least the front surface of the circuit board with a sealing resin in a state where the circuit board is fixed to the lead frame by use of the protrusions.

22. The method of manufacturing a circuit device according to claim 21, wherein, in a step after the hanging leads are partially removed, the circuit board is supported with the leads respectively caulked to the protrusions.

23. The method of manufacturing a circuit device according to claim 21, wherein
the land is formed to be smaller than the circuit board, and
a back surface of the circuit board, which is not covered with the land, is covered with the sealing resin.

24. The method of manufacturing a circuit device according to any of claims 19 to 21, wherein the pad on the circuit board and the respective lead is connected to each other by use of a thin metal wire.
